(19) United States
(12) Patent Application Publication
(10) Pub. No.: US 2026/0280495 A1
(43) Pub. Date: Sep. 17, 2026

(54) STACKED AMPLIFIER WITH LINEARIZATION SCHEME

(71) Applicant: Apple Inc., Cupertino, CA (US)

(72) Inventors: Hongrui Wang, San Jose, CA (US); Hideya Oshima, Santa Clara, CA (US); Milad Darvishi, San Diego, CA (US); Abbas Komijani, Mountain View, CA (US)

(21) Appl. No.: 19/082,092

(22) Filed: Mar. 17, 2025

(51) Int. Cl. H03F 1/32; H03F 3/24; H03F 3/45; H03G 3/30

(52) U.S. Cl. CPC H03F 1/3211; H03F 3/245; H03F 3/45475; H03G 3/3042; H03F 2200/294

(57) ABSTRACT

This disclosure is generally directed to linearization circuitry of a multi-stage amplifier of wireless transmission circuitry. The amplifier may include multiple amplifier stages. The amplifier stages are cascaded such that an output signal of an amplifier stage may be input by a subsequent amplifier stage. Moreover, the amplifier stages are stacked such that the amplifier stages share (e.g., serially receive) a bias signal (e.g., a single bias signal). The linearization circuitry may include at least one operational transconductance amplifier (OTA) and at least one gain correction circuit to reduce a voltage and/or current of undesired signals that may be present based on non-linear behaviors of one or more of the amplifier stages.

### BACKGROUND

The present disclosure relates generally to wireless transmission circuitry, and more specifically to multi-stage amplifiers that amplify transmission signals.

Wireless transmission circuitry may transmit wireless signals via one or more antennas. The wireless transmission circuitry may include one or more amplifiers to amplify the signals before wireless transmission by the antennas. However, the amplifiers may exhibit non-linear behavior degrading a quality of the wireless signals.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, an electronic device may include an antenna and an amplifier. The amplifier may include a first switching device coupled to an amplifier input terminal of the amplifier and may include a second switching device coupled to the first switching device and the antenna. The amplifier may also include an operational transconductance amplifier (e.g., a transconductance amplifier) coupled to the first switching device and the second switching device. The operational transconductance amplifier may provide an impedance less than an impedance threshold based on signals with a frequency greater than a frequency threshold and may provide an impedance greater than or equal to the impedance threshold based on signals with a frequency equal to or less than the frequency threshold.

In another embodiment, wireless transmission circuitry may include a first amplifier stage that may receive a bias signal and an input signal. The first amplifier stage may generate an output signal based on the bias signal and the input signal. The wireless transmission circuitry may also include a second amplifier stage coupled to the first amplifier stage. The second amplifier stage may receive the bias signal and the output signal and generate an amplified signal based on the bias signal and the output signal. The wireless transmission circuitry may also include an operational transconductance amplifier coupled to the first amplifier stage and the second amplifier stage. The operational transconductance amplifier may provide an impedance less than an impedance threshold based on signals with a frequency greater than a frequency threshold and may provide an impedance greater than or equal to the impedance threshold based on signals with a frequency equal to or less than the frequency threshold.

In yet another embodiment, an amplifier may include a first switching device coupled to an amplifier input terminal of the amplifier and may include a second switching device coupled to the first switching device and an amplifier output terminal of the amplifier. The amplifier may also include an operational transconductance amplifier coupled to the first switching device and the second switching device. The operational transconductance amplifier may provide an impedance less than an impedance threshold based on signals with a frequency greater than a frequency threshold and may provide an impedance greater than or equal to the impedance threshold based on signals with a frequency equal to or less than the frequency threshold.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1 including a power amplifier having linearization circuitry, according to embodiments of the present disclosure;

FIG. 4 is a schematic diagram of a receiver of the electronic device of FIG. 1 including a low noise amplifier having linearization circuitry, according to embodiments of the present disclosure;

FIG. 5 is a block diagram of an amplifier such as the power amplifier of FIG. 3 and/or the low noise amplifier of FIG. 4 including the linearization circuitry and multiple cascaded amplifier stages where a first amplifier stage receives an input signal of the amplifier, according to embodiments of the present disclosure;

FIG. 6 is a schematic diagram of a first example embodiment of the amplifier of FIG. 5 including a first amplifier stage having a first N-channel device reverse-stacked with a second amplifier stage having a second N-channel device, according to embodiments of the present disclosure;

FIG. 7 is a schematic diagram of a second example embodiment of the amplifier of FIG. 5 including the first amplifier stage having the first N-channel device reverse-stacked with the second amplifier stage having the second N-channel device and one or more amplifier stages having respective N-channel devices, according to embodiments of the present disclosure;

FIG. 8 is a schematic diagram of a third example embodiment of the amplifier of FIG. 5 including the first amplifier stage having a first P-channel device forward-stacked with the second amplifier stage having a second P-channel device, according to embodiments of the present disclosure;

FIG. 9 is a schematic diagram of a fourth example embodiment of the amplifier of FIG. 5 including the first amplifier stage having the first P-channel device forward-stacked with the second amplifier stage having the second P-channel device and one or more amplifier stages having respective P-channel devices, according to embodiments of the present disclosure;

FIG. 10 is a block diagram of the amplifier of FIG. 3 including the linearization circuitry and multiple cascaded amplifier stages where a first amplifier stage outputs an output signal of the amplifier, according to embodiments of the present disclosure;

FIG. 11 is a schematic diagram of a first example embodiment of the amplifier of FIG. 10 including a first amplifier stage having a first N-channel device forward-stacked with a second amplifier stage having a second N-channel device, according to embodiments of the present disclosure;

FIG. 12 is a schematic diagram of a second example embodiment of the amplifier of FIG. 10 including the first amplifier stage having the first N-channel device forward-stacked with the second amplifier stage having the second N-channel device and one or more amplifier stages having respective N-channel devices, according to embodiments of the present disclosure;

FIG. 13 is a schematic diagram of a third example embodiment of the amplifier of FIG. 10 including the first amplifier stage having a first P-channel device reverse-stacked with the second amplifier stage having a second P-channel device, according to embodiments of the present disclosure; and

FIG. 14 is a schematic diagram of a fourth example embodiment of the amplifier of FIG. 10 including the first amplifier stage having the first P-channel device reverse-stacked with the second amplifier stage having the second P-channel device and one or more amplifier stages having respective P-channel devices, according to embodiments of the present disclosure; and

FIG. 15 is a graph illustrating gain values of the amplifiers of FIGS. 6-14 across input power based on resistance values of first and second resistors of the linearization circuitry, in accordance with embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to linearization circuitry of a multi-stage amplifier. The amplifier may include multiple cascaded amplifier stages for generating an amplified signal. In some embodiments, an electronic device may include one or more antennas and wireless transmission circuitry including the amplifier to transmit the amplified signal.

Each amplifier stage of the amplifier may increase an amplitude of (e.g., amplify) a respective input signal to generate an output signal. For example, an output signal of each amplifier stage may have a greater voltage swing (e.g., voltage amplitude) than an input signal of the amplifier stage based on a gain of the amplifier stage. Moreover, an output signal of an amplifier stage may be used as an input signal of a subsequent amplifier stage. As such, voltage swings of output signals may increase across the amplifier stages. A total gain of the amplifier for generating the amplified signal may correspond to a cumulative gain of each amplifier stage of the amplifier and have a cumulative voltage swing effect added up from each amplifier stage of the amplifier.

Each amplifier stage may receive a bias signal to amplify input signals. Multiple amplifier stages are stacked, either reverse-stacked or forward-stacked to share the bias signal. When reverse-stacked, a last amplifier stage providing an output signal of the amplifier may set (e.g., set a value for) a bias signal current draw of the amplifier stages sharing the bias signal. When forward-stacked, a first amplifier stage receiving an input signal of the amplifier may set (e.g., set a value for) a bias signal current draw of the amplifier stages sharing the bias signal. For example, a bias input terminal of a first amplifier stage may receive the bias signal from a power source. Moreover, a bias output terminal of each amplifier stage, except a last amplifier stage, may be coupled to (e.g., serially coupled to) a bias input terminal of a subsequent amplifier stage. Each amplifier stage, except for the last amplifier stage, may serially provide (e.g., share) the bias signal (e.g., a single bias signal) to a subsequent amplifier stage. A bias output terminal of the last amplifier stage may be coupled to a ground terminal. In some cases, the amplifier may have a reduced electrical power consumption based on sharing the bias signal with multiple amplifier stages (e.g., instead of each amplifier stage receiving a separate bias signal).

As mentioned above, voltage swings of output signals may increase across the amplifier stages. An increase in the voltage swing of output signals may decrease a headroom voltage between the bias signal and the output signals across the amplifier stages. A non-linear gain expansion or compression of an amplifier stage may further decrease a headroom voltage of the amplifier stage and/or subsequent amplifier stages sharing the bias signal below a voltage threshold. Moreover, an electrical current consumption of amplifier stages may increase based on the increase in the voltage swing of the output signals across the amplifier stages. The non-linear gain expansion or compression of the amplifier stage may further increase the electrical current consumption of the amplifier stage and/or the subsequent amplifier stages sharing the bias signal above a current threshold.

In some cases, the non-linear behavior of the amplifier stages may cause undesired voltage and/or current interactions between the amplifier stages sharing the bias signal. For example, in specific cases, the undesired voltage and/or current interactions between the amplifier stages may degrade and/or distort transmission data modulated on the amplified signal. In the embodiments discussed herein, the amplifier may include linearization circuitry to improve linearity of a gain of one or more of the amplifier stages and reduce degradation and/or distortion of the modulated transmission data of the amplified signal. The linearization circuitry may include at least one operational transconductance amplifier (OTA) and at least one gain correction circuit to suppress undesired signals that may be caused by the non-linear behaviors.

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic).

The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10.

The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol.

The network interface 26 may include, for example, one or more interfaces for a personal area network (PAN), such as an ultra-wideband (UWB) or a BLUETOOTH network, a local area network (LAN) or wireless local area network (WLAN), such as a network employing one of the IEEE 802.11x family of protocols (e.g., WI-FI), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX), mobile broadband Wireless networks (mobile WIMAX), asynchronous digital subscriber lines (e.g., ADSL, VDSL), digital video broadcasting-terrestrial (DVB-T) network and its extension DVB Handheld (DVB-H) network, ultra-wideband (UWB) network, alternating current (AC) power lines, and so forth.

As illustrated, the network interface 26 may include a transceiver or modem 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter.

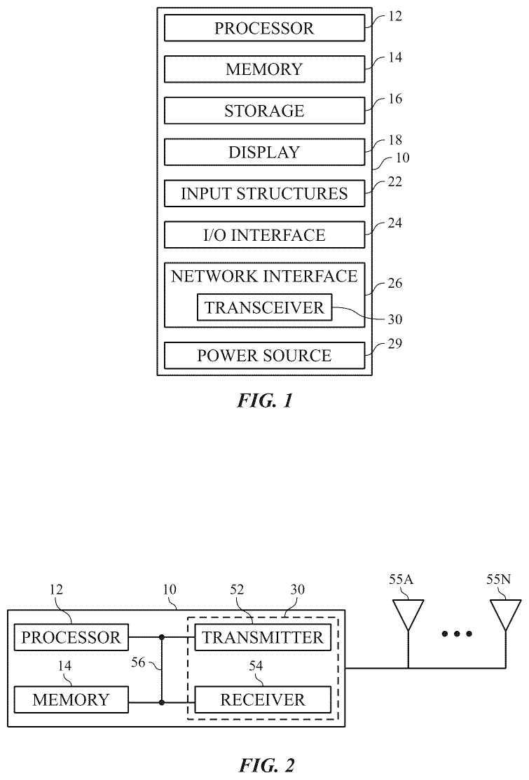

FIG. 2 is a functional diagram of the electronic device 10 of FIG. 1, according to embodiments of the present disclosure. As illustrated, the processor 12, the memory 14, the transceiver 30, a transmitter or wireless transmission circuitry 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

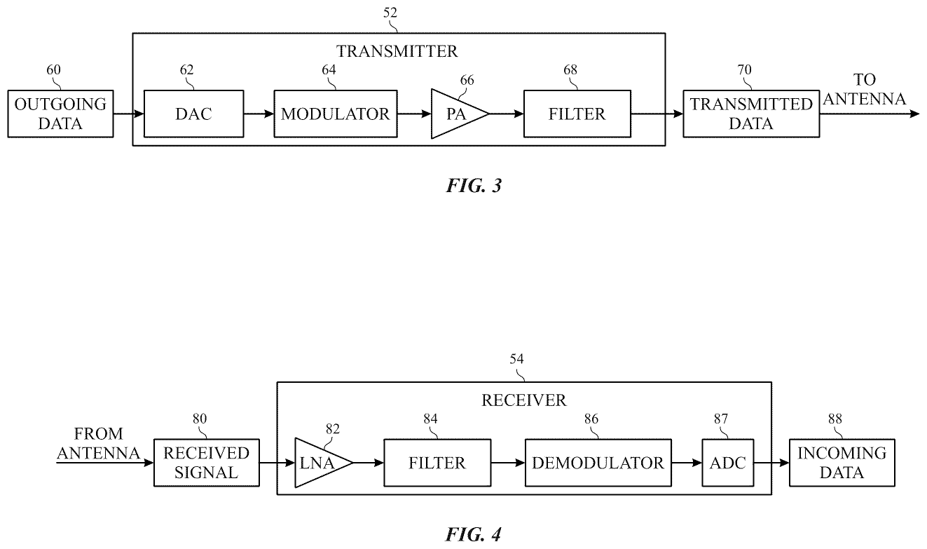

FIG. 3 is a schematic diagram of the transmitter 52 (e.g., the wireless transmission circuitry), according to embodiments of the present disclosure. As illustrated, the transmitter 52 may receive outgoing data 60 (e.g., transmission data) in the form of a digital signal to be transmitted via the one or more antennas 55. A digital-to-analog converter 62 of the transmitter 52 may convert the digital signal to an analog signal, and a modulator 64 may combine the converted analog signal with a carrier signal to generate a radio wave.

A power amplifier 66 receives the modulated signal carrying (e.g., including) the outgoing data 60 from the modulator 64. The power amplifier 66 may include multiple cascaded amplifier stages. Each amplifier stage of the power amplifier 66 may amplify the modulated signal with a gain corresponding to a portion of a total gain of the power amplifier 66 to generate an amplified signal. As such, the power amplifier 66 may amplify the modulated signal to a suitable level to drive transmission of the amplified signal carrying the outgoing data 60 via the one or more antennas 55. The power amplifier 66 may include linearization circuitry to improve a quality of the amplified signal carrying the outgoing data 60 by reducing (e.g., suppressing) undesired gain expansions or compressions of one or more of the cascaded amplifier stages.

A filter 68 (e.g., gain correction circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

The power amplifier 66 and/or the filter 68 may be referred to as part of a radio frequency front end, and more specifically, a transmit front end of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 68 if the power amplifier 66 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier 82 may amplify the received signal 80 (e.g., received analog signal) to a suitable level for the receiver 54 to process. The low noise amplifier 82 may include multiple cascaded amplifier stages. Each amplifier stage of the low noise amplifier 82 may amplify the received signal 80 with a gain corresponding to a portion of a total gain of the low noise amplifier 82 to generate an amplified signal. As such, the low noise amplifier 82 may amplify the received signal 80 to a suitable level to drive transmission of the amplified signal carrying the outgoing data 60 via the one or more antennas 55. The power amplifier 66 may include linearization circuitry to improve a quality of the amplified signal carrying the outgoing data 60 by reducing (e.g., suppressing) undesired gain expansions or compressions of one or more of the cascaded amplifier stages.

A filter 84 (e.g., filter circuitry and/or software) may remove undesired noise from the received signal 80, such as cross-channel interference. The filter 84 may also remove additional signals received by the one or more antennas 55 that are at frequencies other than the desired signal. The filter 84 may include any suitable filter or filters to remove the undesired noise or signals from the received signal 80, such as a bandpass filter, a bandstop filter, a low pass filter, a high pass filter, and/or a decimation filter. The low noise amplifier 82 and/or the filter 84 may be referred to as part of the RFFE, and more specifically, a receiver front end (RXFE) of the electronic device 10.

A demodulator 86 may remove a radio frequency carrier signal and/or extract a demodulated signal (e.g., an envelope signal) from the filtered signal for processing. An analog-to-digital converter (ADC) 87 may receive the demodulated analog signal and convert the signal to a digital signal of incoming data 88 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter.

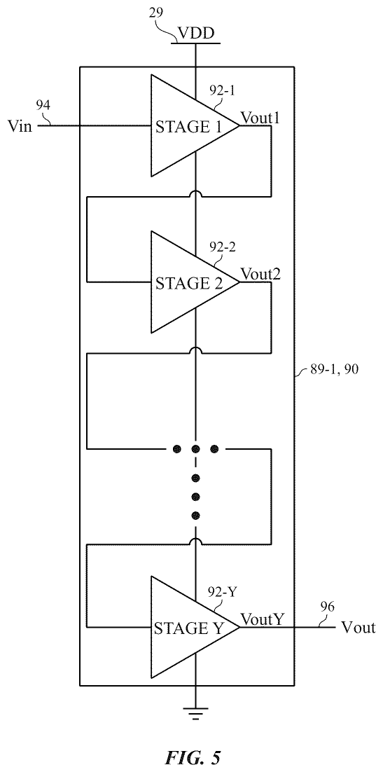

FIG. 5 is a block diagram of an amplifier 89-1 including linearization circuitry 90 and multiple (e.g., 2, 3, 4, 5 or more) cascaded amplifier stages 92 where a first amplifier stage 92-1 receives an input signal of the amplifier 89-1, according to embodiments of the present disclosure. In some embodiments, the amplifier 89-1 may correspond to an embodiment of the power amplifier 66 of FIG. 3. In alternative or additional embodiments, the amplifier 89-1 may correspond to an embodiment of the low noise amplifier 82 of FIG. 4.

The amplifier 89-1 may include any number of amplifier stages 92 including the first amplifier stage 92-1, a second amplifier stage 92-2, and a Yth amplifier stage 92-Y. Each amplifier stage 92 may amplify the input signal to generate a respective output signal (e.g., a respective output voltage signal labeled as Vₒᵤₜ₁, Vₒᵤₜ₂, V_{outY}, among others) based on a gain. Moreover, the amplifier stages 92 are cascaded such that each amplifier stage 92 may output a respective output signal to a subsequent amplifier stage.

For example, the amplifier 89-1 may receive the modulated signal (e.g., the input signal, Vᵢₙ) carrying the outgoing data 60 to generate an amplified signal (e.g., Vₒᵤₜ) for transmission. An amplifier input terminal or port 94 may be coupled to an input terminal or port of the first amplifier stage 92-1. The first amplifier stage 92-1 may amplify the modulated signal based on a gain. In some cases, the amplifier 89-1 may output a first output signal (e.g., Vₒᵤₜ₁) as an amplified signal via an amplifier output terminal or port 96. Alternatively or additionally, the second amplifier stage 92-2 may receive the first output signal (e.g., Vₒᵤₜ₁) of the first amplifier stage 92-1.

The second amplifier stage 92-2 may amplify the first output signal based on a gain. That is, the second amplifier stage 92-2 may amplify the modulated signal, as amplified by the first amplifier stage 92-1, based on a gain to generate a second output signal (e.g., Vₒᵤₜ₂). In some cases, the amplifier 89-1 may output the second output signal (e.g., Vₒᵤₜ₂) as the amplified signal (e.g., Vₒᵤₜ) via the amplifier output terminal 96. Alternatively or additionally, the second amplifier stage 92-2 may output the second output signal (e.g., Vₒᵤₜ₂) to a subsequent amplifier stage coupled thereto (e.g., the Yth amplifier stage 92-Y) for further amplification of the modulated signal.

In different embodiments, the amplifier 89-1 may include a different number of amplifier stages 92 for amplifying the modulated signal. Moreover, as discussed above, the modulated signal may carry (e.g., include) the outgoing data 60. As such, the amplifier 89-1 may output the amplified signal carrying the outgoing data 60 with an amplified voltage swing based on a total gain of the amplifier stages 92. The total gain of the amplifier stages 92 may correspond to a cumulative gain of each of the amplifier stages 92. It should be appreciated that the amplifier stages 92 may have equal, substantially or relatively equal, or different gain values.

With the foregoing in mind, the amplifier stages 92 may receive (e.g., share) a bias signal (e.g., VDD) from the power source 29 discussed above for amplifying the modulated signal. In the depicted embodiment, the first amplifier stage 92-1 may receive the bias signal from the power source 29. Moreover, the first amplifier stage 92-1 may provide (e.g., output) the bias signal to the second amplifier stage 92-2. The second amplifier stage 92-2 may provide (e.g., output) the bias signal to a subsequent amplifier stage (e.g., the Yth amplifier stage 92-Y), and so on. As such, the amplifier 89-1 may have a reduced electrical power consumption based on stacking the amplifier stages 92 and sharing the bias signal (e.g., instead of each amplifier stage 92 receiving a separate bias signal).

The amplifier 89-1 may include linearization circuitry 90 to improve linearity of the total gain of the amplifier 89-1, as will be appreciated. For example, the linearization circuitry 90 may increase a headroom voltage between the bias signal and output signals of the first amplifier stage 92-1, the second amplifier stage 92-2, and so on. Alternatively or additionally, the linearization circuitry 90 may decrease an electrical current consumption of the first amplifier stage 92-1 and/or the second amplifier stage 92-2.

In some cases, the linearization circuitry 90 may reduce non-linearities of the bias signal received by one or more of the stacked amplifier stages 92. For example, the linearization circuitry 90 may reduce a non-linear gain expansion or compression of one or more of the amplifier stages 92 adversely affecting (e.g., interacting with) the shared bias signal between the amplifier stages 92. Accordingly, the linearization circuitry 90 may improve a signal quality and/or reduce a degradation and/or distortion of the amplified signal (e.g., Vₒᵤₜ) carrying the outgoing data 60.

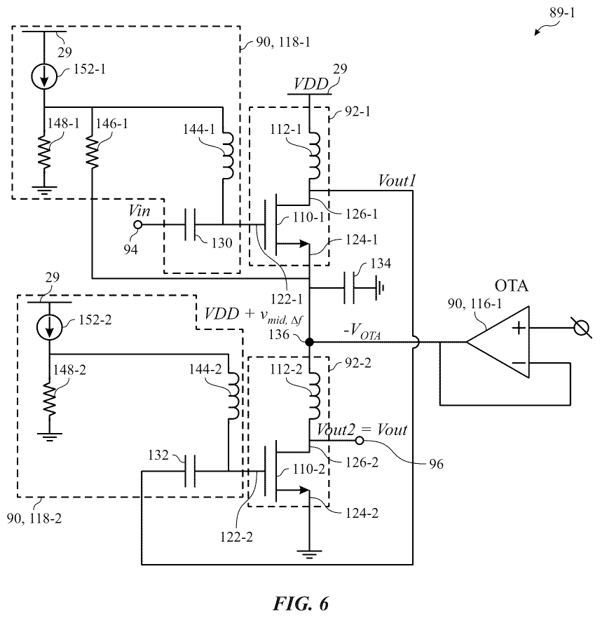

FIG. 6 is a schematic diagram of the amplifier 89-1 including the linearization circuitry 90 with the first amplifier stage 92-1 having a first N-channel device 110-1 reverse-stacked with the second amplifier stage 92-2 having a second N-channel device 110-2, according to embodiments of the present disclosure. The first N-channel device 110-1 and/or the second N-channel device 110-2 may include any viable N-channel transistor such as a metal-oxide-semiconductor field-effect transistor (MOSFET), among other possibilities. In some embodiments, the first amplifier stage 92-1 may include a first inductor 112-1 and the first N-channel device 110-1 (e.g., a first switching device), and the second amplifier stage 92-2 may include a second inductor 112-2 and the second N-channel device 110-2 (e.g., a second switching device). The linearization circuitry 90 may include a first OTA 116-1 (e.g., a first transconductance amplifier) and a first N-channel gain correction circuit 118-1. The first N-channel gain correction circuit 118-1 may be coupled to a first control terminal or port 122-1 and a first bias output terminal or port 124-1 of the first amplifier stage 92-1.

It should be appreciated that the first amplifier stage 92-1 and/or the second amplifier stage 92-2 may include one or more P-channel devices in lieu or in addition to the first N-channel device 110-1 and the second N-channel device 110-2, respectively. Moreover, the first amplifier stage 92-1 and/or the second amplifier stage 92-2 may include additional or alternative circuit components. For example, the first amplifier stage 92-1 and/or the second amplifier stage 92-2 may include a transformer in lieu of or in addition to the first inductor 112-1 and the second inductor 112-2, respectively.

The first N-channel device 110-1 may have a gate terminal or port (e.g., the first control terminal 122-1), a drain terminal or port (e.g., a first bias input terminal 126-1), and a source terminal or port (e.g., the first bias output terminal 124-1). The second N-channel device 110-2 may have a gate terminal or port (e.g., the second control terminal 122-2), a drain terminal or port (e.g., a second bias input terminal 126-2), and a source terminal or port (e.g., the second bias output terminal 124-2). It should be appreciated that the first amplifier stage 92-1 and the second amplifier stage 92-2 may use any viable switching circuitry in lieu of or in addition to the first N-channel device 110-1 and/or the second N-channel device 110-2, respectively.

The gate terminal of the first N-channel device 110-1 may be coupled to the amplifier input terminal 94 via a first coupling capacitor 130. The gate terminal of the first N-channel device 110-1 may receive the modulated signal (e.g., input signal, Vᵢₙ) for amplification. The drain terminal of the first N-channel device 110-1 may be coupled to the power source 29 via the first inductor 112-1. The drain terminal of the first N-channel device 110-1 may receive the bias signal (e.g., VDD) for amplifying the modulated signal. The first N-channel device 110-1 may amplify the modulated signal (e.g., the input signal, Vᵢₙ) based on a gain.

The first amplifier stage 92-1 may output the modulated signal (e.g., the first output signal, Vₒᵤₜ₁), as amplified by the first N-channel device 110-1, by the drain terminal of the first N-channel device 110-1. The drain terminal of the first N-channel device 110-1 may be coupled to the gate terminal of the second N-channel device 110-2 via a second coupling capacitor 132. As such, the gate terminal of the second N-channel device 110-2 may receive the modulated signal (e.g., the first output signal, Vₒᵤₜ₁), as amplified by the first N-channel device 110-1.

The first N-channel device 110-1 may output the bias signal by the respective source terminal. The source terminal of the first N-channel device 110-1 may be coupled to the drain terminal of the second N-channel device 110-2 via the second inductor 112-2. As such, the drain terminal of the second N-channel device 110-2 may receive the bias signal from the source terminal of the first N-channel device 110-1 for amplifying the modulated signal. In some embodiments, the amplifier 89-1 may include a first bypass capacitor 134 coupling a first node 136 between the first N-channel device 110-1 and the second inductor 112-2 to a ground terminal. In some cases, the first bypass capacitor 134 may ground at least a portion of noises between the first N-channel device 110-1 and the second inductor 112-2.

The second N-channel device 110-2 may receive the bias signal to amplify the modulated signal (e.g., the first output signal, Vₒᵤₜ₁) based on a gain. It should be appreciated that the first N-channel device 110-1 and the second N-channel device 110-2 may provide equal, substantially or relatively equal, or different gain values. The second amplifier stage 92-2 may output the modulated signal (e.g., the second output signal, the amplified signal), as amplified by the first N-channel device 110-1 and the second N-channel device 110-2, by the drain terminal of the second N-channel device 110-2. In the depicted embodiment, the drain terminal of the second N-channel device 110-2 may be coupled to the amplifier output terminal 96. As such, the amplifier 89-1 may output the second output signal (e.g., Vₒᵤₜ₂) as the amplified signal (e.g., Vₒᵤₜ) via the amplifier output terminal 96.

With the foregoing in mind, a frequency of the bias signal (e.g., VDD) may be zero (e.g., near zero, relatively zero) or below a frequency threshold. Moreover, the second amplifier stage 92-2 may receive the bias signal from the first amplifier stage 92-1 over the first node 136. As such, a frequency of the bias signal at the first node 136 between the first amplifier stage 92-1 and the second amplifier stage 92-2 may be zero (e.g., near zero, relatively zero) or below the frequency threshold.

If not compensated for, in some cases, a non-linear gain expansion or compression of the first amplifier stage 92-1 and/or the second amplifier stage 92-2, among other things, may cause an undesired amplitude mis-match between the input signal (e.g., Vᵢₙ) and the amplified signal (e.g., Vₒᵤₜ). For example, a nonlinearity (e.g., second-order nonlinearity) of the amplifier stages 92. different input voltage swings at the gate terminals of the N-channel devices 110 may cause a modulation current magnitude difference between the amplifier stages 92. The undesired current magnitude difference may interact with fundamental frequencies of the input signal (e.g., fundamental frequencies of a two-tone input signal) at the gate terminals. Moreover, the current magnitude difference, among other reasons, may cause generation of an undesired ripple signal (e.g., V_{mid}, Δf) at the first node 136 between the first amplifier stage 92-1 and the second amplifier stage 92-2. If not compensated for, the ripple signal (e.g., intermodulation distortions (IM3) of the ripple signal) may be combined with the output signal and/or may disturb a headroom voltage and/or an electrical current consumption of the amplifier 89-1. As such, the nonlinearity between the amplifier stages 92 may adversely affect a signal quality of the amplified signal (e.g., Vₒᵤₜ) being generated and/or transmitted.

The linearization circuitry 90 may reduce a voltage and/or current of the ripple signal and therefore improve the signal quality of the amplified signal carrying the outgoing data 60. The linearization circuitry 90 may include the first OTA 116-1 and the first N-channel gain correction circuit 118-1 coupled to the first node 136 between the first amplifier stage 92-1 and the second amplifier stage 92-2. The first OTA 116-1 may provide a low impedance ground path to signals having a frequency greater than or equal to the frequency threshold. The first OTA 116-1 may reduce a voltage and/or current of the ripple signal by grounding at least a portion of the ripple signal (e.g., V_{OTA}). Moreover, the first N-channel gain correction circuit 118-1 may reduce a voltage or current of a remaining portion of the ripple signal.

For example, a first input terminal or port (e.g., a positive input terminal or port) of the first OTA 116-1 may be coupled to a controlled voltage source. A second input terminal or port (e.g., a negative input terminal or port) of the first OTA 116-1 may be coupled to an output terminal or port of the first OTA 116-1. Moreover, the OTA output terminal may be coupled to the first node 136 between the first amplifier stage 92-1 and the second amplifier stage 92-2. A transconductance of the first OTA 116-1 and a controlled voltage provided to the first OTA 116-1 input terminal may be selected such that the OTA output terminal may provide a relatively low impedance less than an impedance threshold to signals having a frequency range including that of the ripple signal.

In some embodiments, the transconductance and/or the controlled voltage may be selected during manufacturing of the amplifier 89-1. In alternative or additional embodiments, a processor and/or controller coupled to the amplifier 89-1, such as the processor 12 discussed above, may dynamically select (e.g., adjust) the transconductance and/or the controlled voltage. The OTA output terminal may provide an impedance of less than 100 ohms (Ω), less than 240 Ω, less than 1 kΩ, less than 10 kΩ, less than 13 kΩ, less than 100 kΩ, and so on, among other possibilities, to signals having a frequency greater than or equal to the frequency threshold (e.g., AC signals). Accordingly, the first OTA 116-1 may draw at least a portion of electrical currents of the first node 136 and reduce a voltage and/or power of the ripple signal to reduce undesired (e.g., non-linear) behavior of amplifier 89-1.

The first N-channel gain correction circuit 118-1 may include a first choke inductor 144-1, the first coupling capacitor 130, a first resistor 146-1, a second resistor 148-1, and a first current source 152-1. The first choke inductor 144-1 may be coupled to the gate terminal of the first N-channel device 110-1 and the first coupling capacitor 130. The first resistor 146-1 may have a first terminal or port coupled to the first choke inductor 144-1, the second resistor 148-1, and the first current source 152-1, and a second terminal or port coupled to the first source terminal of the first N-channel device 110-1. The second resistor 148-1 may have a first terminal or port coupled to the first resistor 146-1, the first current source 152-1, and the first choke inductor 144-1, and a second terminal or port coupled to a ground terminal or port. The first current source 152-1 may be coupled to the power source 29 to receive a supply voltage (e.g., the bias signal). Moreover, the first current source 152-1 may output electrical current to the first resistor 146-1, the second resistor 148-1, and the first choke inductor 144-1. A resistance values of the first resistor 146-1 and the second resistor 148-1, an inductance value of the first choke inductor 144-1, and an output current value of the first current source 152-1 may be selected to reduce a voltage or current of the ripple signal.

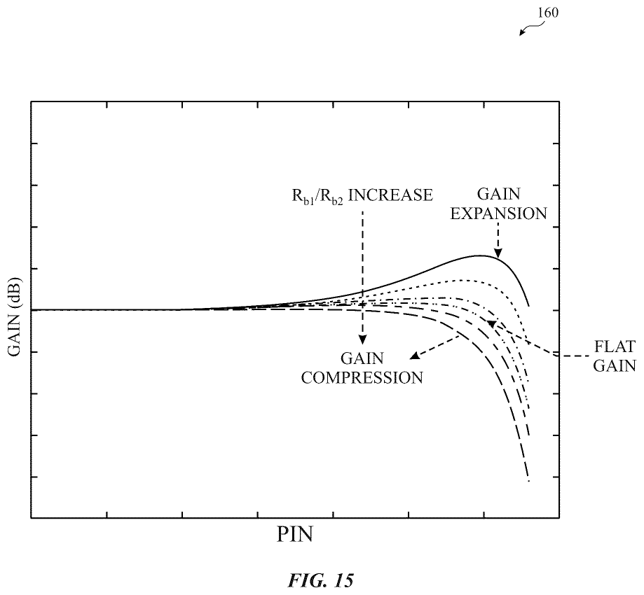

Referring now to FIG. 15, a graph 160 illustrates example gain value changes (in decibels (dB)) of the amplifiers 89 based on resistance values of the first resistor 146-1 and the second resistor 148-1. For example, a greater resistance value of the second resistor 148-1 compared to the first resistor 146-1 may boot-strap the first N-channel device 110-1 to reduce a voltage and/or current of the ripple signal by linearizing (e.g., compressing, reducing) an undesired gain expansion of the first N-channel device 110-1. Moreover, a greater resistance value of the first resistor 146-1 compared to the second resistor 148-1 may reduce the voltage and/or current of the ripple signal by linearizing (e.g., expanding, increasing) an undesired gain compression of the first N-channel device 110-1.

Referring back to FIG. 6, the resistance values of the first resistor 146-1 and the second resistor 148-1, the inductance value of the first choke inductor 144-1, and the output current value of the first current source 152-1 may be selected during manufacturing of the amplifier 89-1. In alternative or additional embodiments, a processor and/or controller coupled to the amplifier 89-1, such as the processor 12 discussed above, may dynamically select (e.g., adjust) such values of the components of the first N-channel gain correction circuit 118-1. For example, the resistance value of the first resistor 146-1 and/or the second resistor 148-1, the inductance value of the first choke inductor 144-1, and/or the output current value of the first current source 152-1 may be adjustable. Accordingly, the linearization circuitry 90 may reduce a non-linear gain expansion or compression of the amplifier 89-1.

Similarly, the linearization circuitry 90 may include a second N-channel gain correction circuit 118-2 to reduce a non-linear gain expansion or compression of the amplifier 89-1. The second N-channel gain correction circuit 118-2 may be coupled to a second control terminal or port 122-2 and a second bias output terminal or port 124-2 of the second N-channel device 110-2. The second N-channel gain correction circuit 118-2 may include a first choke inductor 144-2, the second coupling capacitor 132, a first resistor 146-2, a second resistor 148-2, and a first current source 152-2.

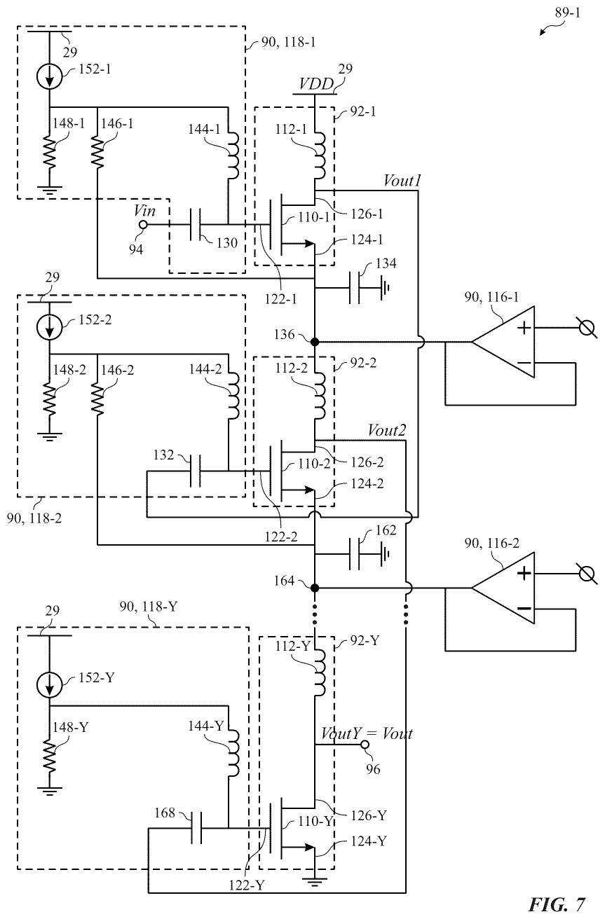

FIG. 7 is a schematic diagram of the amplifier 89-1 including the linearization circuitry 90 and the first amplifier stage 92-1 having the first N-channel device 110-1 reverse-stacked with the second amplifier stage 92-2 having the second N-channel device 110-2 and at least the Yth amplifier stage 92-Y having a Yth N-channel device 110-Y, according to embodiments of the present disclosure. Each amplifier stage 92 may include a respective N-channel device and a respective inductor. For example, in the depicted embodiment, the first amplifier stage 92-1 may include the first inductor 112-1 and the first N-channel device 110-1, the second amplifier stage 92-2 may include the second inductor 112-2 and the second N-channel device 110-2, and the Yth amplifier stage 92-Y may include the Yth inductor 112-Y and the Yth N-channel device 110-Y (e.g., a Yth switching device).

It should be appreciated that the amplifier 89-1 may include any viable number of amplifier stages 92 (e.g., 2, 3, 4, 5, and so on, N). Each N-channel device may include any viable N-channel transistor such as a MOSFET, among other possibilities. Moreover, the first amplifier stage 92-1 and/or the second amplifier stage 92-2 may include additional or alternative circuit components. For example, each amplifier stage 92 may include one or more P-channel devices in lieu or in addition to the respective N-channel device and/or a transformer in lieu of or in addition to the respective inductor.

The first N-channel device 110-1 may have the gate terminal (e.g., the first control terminal 122-1), the drain terminal (e.g., the first bias input terminal 126-1), and the source terminal (e.g., the first bias output terminal 124-1). The second N-channel device 110-2 may have the gate terminal (e.g., the second control terminal 122-2), the drain terminal (e.g., the second bias input terminal 126-2), and the source terminal (e.g., the second bias output terminal 124-2). Similarly, the Yth N-channel device 110-Y may have a gate terminal (e.g., a Yth control terminal 122-Y), a drain terminal (e.g., a Yth bias input terminal 126-Y), and a source terminal (e.g., a Yth bias output terminal 124-Y). It should be appreciated that each amplifier stage 92 may use any viable switching circuitry in lieu of or in addition to the respective N-channel devices 110.

In the depicted embodiment, the first bias input terminal 126-1 of the first N-channel device 110-1 may be coupled to the power source 29 via the first inductor 112-1. Moreover, the first bias output terminal 124-1 of the first N-channel device 110-1 may be coupled to the second bias input terminal 126-2 of the second N-channel device 110-2 via the second inductor 112-2. As such, the first N-channel device 110-1 may receive the bias signal (e.g., VDD) from the power source 29 and output (e.g., share) the bias signal to the second N-channel device 110-2. Similarly, the second bias output terminal 124-2 of the second N-channel device 110-2 may be coupled to a subsequent bias input terminal of a subsequent N-channel device via a subsequent inductor.

The second bias output terminal 124-2 may be coupled to the Yth bias input terminal 126-Y of the Yth N-channel device 110-Y via the Yth inductor 112-Y. As such, the bias input terminal of the subsequent N-channel device (e.g., the Yth N-channel device 110-Y) may receive the bias signal. That is, the N-channel device of each amplifier stage 92 may share the bias signal with a subsequent amplifier stage. As mentioned above, the amplifier 89-1 may include any viable number of amplifier stages 92. Accordingly, the second bias output terminal 124-2 may be coupled to any number of additional N-channel devices not shown before the bias signal is shared with a last N-channel device (e.g., the Yth N-channel device 110-Y).

The amplifier stages 92 are cascaded such that each amplifier stage 92 may output a respective output signal to a subsequent amplifier stage. The first control terminal 122-1 of the first N-channel device 110-1 may be coupled to the amplifier input terminal 94 via the first coupling capacitor 130 to receive the modulated signal (e.g., input signal, Vᵢₙ). The first N-channel device 110-1 may amplify the modulated signal (e.g., the input signal, Vᵢₙ) based on a gain. The first amplifier stage 92-1 may output the modulated signal (e.g., the first output signal, Vₒᵤₜ₁), as amplified by the first N-channel device 110-1, by the first bias input terminal 126-1 of the first N-channel device 110-1.

The first bias input terminal 126-1 of the first N-channel device 110-1 may be coupled to the second control terminal 122-2 of the second N-channel device 110-2 via the second coupling capacitor 132. As such, the second N-channel device 110-2 may receive the modulated signal (e.g., the first output signal, Vₒᵤₜ₁), as amplified by the first N-channel device 110-1. Similarly, the second amplifier stage 92-2 may output the modulated signal (e.g., the second output signal, Vₒᵤₜ₂), as amplified by the first N-channel device 110-1 and the second N-channel device 110-2, by the second bias input terminal 126-2 of the second N-channel device 110-2.

The second bias input terminal 126-2 of the second N-channel device 110-2 may be coupled to a control terminal of a subsequent N-channel device. In the depicted embodiment, the second bias input terminal 126-2 of the second N-channel device 110-2 may be coupled to the Yth control terminal 122-Y of the Yth N-channel device 110-Y via a Yth coupling capacitor 168. As such, the Yth N-channel device 110-Y may receive the modulated signal (e.g., the second output signal, Vₒᵤₜ₂), as amplified by the first N-channel device 110-1 and the second N-channel device 110-2. The Yth bias input terminal 126-Y of the Yth N-channel device 110-Y may be coupled to the amplifier output terminal 96. Accordingly, the amplifier 89-1 may output the Yth output signal (e.g., V_{outY}) as the amplified signal (e.g., Vₒᵤₜ) via the amplifier output terminal 96. As mentioned above, the amplifier 89-1 may include any viable number of amplifier stages 92.

It should be appreciated that each N-channel device may amplify the modulated signal based on equal, substantially or relatively equal, or different gain values. In some embodiments, the amplifier 89-1 may include the first bypass capacitor 134 and a second bypass capacitor 162 coupling a second node 164 between the second N-channel device 110-2 and the Yth inductor 112-Y to the ground terminal. In some cases, the second bypass capacitor 162 may ground at least a portion of noises between the second N-channel device 110-2 and the Yth inductor 112-Y.

In the depicted embodiment, the linearization circuitry 90 may include the first OTA 116-1, a second OTA 116-2 (e.g., a second transconductance amplifier), a Yth OTA 116-Y (e.g., a Yth transconductance amplifier), the first N-channel gain correction circuit 118-1, a second N-channel gain correction circuit 118-2, and a Yth N-channel gain correction circuit 118-Y. In some cases, the linearization circuitry 90 may reduce a voltage and/or current of one or more undesired ripple signals, for example, on the first node 136 and/or the second node 164. As such, the linearization circuitry 90 may improve the signal quality of the amplified signal carrying the outgoing data 60.

The first OTA 116-1 may be coupled to the first bias output terminal 124-1 of the first amplifier stage 92-1 and the second bias output terminal 124-2 of the second amplifier stage 92-2. The second OTA 116-2 may be coupled to the second bias output terminal 124-2 of the second amplifier stage 92-2 and the Yth bias output terminal 124-Y of the Yth amplifier stage 92-Y. It should be appreciated that the linearization circuitry 90 may include one or more additional OTAs, for example, coupled to a bias input terminal and/or a bias output terminal of one or more additional amplifier stages 92 not shown for simplicity. Each OTA 116 may provide a low impedance ground path to signals having a frequency greater than or equal to the frequency threshold to reduce a voltage and/or current of an undesired ripple signal.

For example, a first input terminal (e.g., a positive input terminal) of each OTA 116 may be coupled to the controlled voltage source. A second input terminal (e.g., a negative input terminal) of each OTA 116 may be coupled to an output terminal of the respective OTA 116. Moreover, each OTA 116 output terminal may be coupled to a bias input terminal and/or a bias output terminal of one or more of the amplifier stages 92. A transconductance of each OTA 116 and a controlled voltage provided to each OTA 116 input terminal may be selected such that the respective OTA 116 output terminal may provide a relatively low impedance less than an impedance threshold to signals having a frequency range including that of an undesired ripple signal.

In some embodiments, the transconductance and/or the controlled voltage source of each OTA 116 may be selected during manufacturing of the amplifier 89-1. In alternative or additional embodiments, a processor and/or controller coupled to the amplifier 89-1, such as the processor 12 discussed above, may dynamically select (e.g., adjust) the transconductance and/or the controlled voltage of the controlled sources coupled to each OTA 116. Each OTA 116 output terminal may provide an impedance of less than 100 ohms (Ω), less than 240 Ω, less than 1 kΩ, less than 10 kΩ, less than 13 kΩ, less than 100 kΩ, and so on, among other possibilities, to signals having a frequency greater than or equal to than the frequency threshold (e.g., AC signals). Accordingly, the OTAs 116 may draw at least a portion of electrical currents of an undesired ripple signal and reduce a voltage and/or power of the undesired ripple signal to reduce undesired (e.g., non-linear) behavior of amplifier 89-1.

The first N-channel gain correction circuit 118-1 may be coupled to the first control terminal 122-1 and the first bias output terminal 124-1 of the first amplifier stage 92-1. The second N-channel gain correction circuit 118-2 may be coupled to the second control terminal 122-2 and the second bias output terminal 124-2 of the second N-channel device 110-2. In the depicted embodiment, the Yth N-channel gain correction circuit 118-Y may be coupled to the Yth control terminal 122-Y. For example, the Yth N-channel gain correction circuit 118-Y may not include a respective first resistor 146. Alternatively or additionally, the Yth N-channel gain correction circuit 118-Y may include a respective first resistor 146 coupled to the Yth bias output terminal 124-Y of the Yth N-channel device 110-Y. It should be appreciated that the linearization circuitry 90 may include one or more additional N-channel gain correction circuits 118, for example, coupled to a control terminal and a bias output terminal of one or more additional N-channel device (not shown). Each N-channel gain correction circuit 118 may reduce a voltage or current of an undesired ripple signal.

In some embodiments, each N-channel gain correction circuit 118 may include a choke inductor (e.g., choke inductors 144-1, 144-2, and/or 144-Y), a coupling capacitor (e.g., the first coupling capacitor 130, the second coupling capacitor 132, the Yth coupling capacitor 168), a first resistor 146 (e.g., a first resistor 146-1, 146-2, and/or 146-Y), a second resistor 148 (e.g., a second resistor 148-1, 148-2, and/or 148-Y), and a current source 152 (e.g., current sources 152-1, 152-2, and 152-Y). As mentioned above, in the depicted embodiment, the Yth N-channel gain correction circuit 118-Y may be coupled to the Yth control terminal 122-Y. For example, the Yth N-channel gain correction circuit 118-Y may not include a respective first resistor 146. Alternatively or additionally, the Yth N-channel gain correction circuit 118-Y may include a respective first resistor 146 coupled to the Yth bias output terminal 124-Y of the Yth N-channel device 110-Y.

The choke inductor 144 of each N-channel gain correction circuit 118 may be coupled to a control terminal of a respective N-channel device terminal and the coupling capacitor. The first resistor 146 of each N-channel gain correction circuit 118 may have a first terminal coupled to a respective choke inductor 144, second resistor 148, and current source, and a second terminal coupled to a bias output terminal of the respective N-channel device. The second resistor 148 of each N-channel gain correction circuit 118 may have a first terminal coupled to a respective first resistor 146, current source, and choke inductor 144, and a second terminal coupled to a ground terminal. Each current source of each N-channel gain correction circuit 118 may be coupled to the power source 29 to receive a supply voltage (e.g., the bias signal). Moreover, the current source of each N-channel gain correction circuit 118 may output electrical current to a respective first resistor 146, second resistor 148, and choke inductor 144.

For each N-channel gain correction circuit 118, resistance values of the respective first resistor 146 and the second resistor 148, an inductance value of the respective choke inductor 144, and an output current value of the respective current source may be selected to reduce a voltage or current of an undesired ripple signal. Referring now to FIG. 15, the graph 160 illustrates example gain value changes of the amplifiers 89 based on resistance values of the first resistor 146-1 and the second resistor 148-1. For example, a greater resistance value of the second resistor 148 compared to the first resistor 146 may boot-strap a respective N-channel device to reduce a voltage and/or current of the ripple signal by linearizing (e.g., compressing) an undesired gain expansion of the respective N-channel device. Moreover, a greater resistance value of the first resistor 146 compared to the second resistor 148 may reduce a voltage and/or current of the ripple signal by linearizing (e.g., expanding) an undesired gain compression of the respective N-channel device.

Referring back to FIG. 7, the resistance values of each first resistor 146 and second resistor 148, the inductance value of each choke inductor 144, and the output current value of each current source may be selected during manufacturing of the amplifier 89-1. In alternative or additional embodiments, a processor and/or controller coupled to the amplifier 89-1, such as the processor 12 discussed above, may dynamically select (e.g., adjust) such values of the components of one or more of the N-channel gain correction circuits 118. For example, the resistance value of each first resistor 146 and/or each second resistor 148, the inductance value of each choke inductor 144, and/or the output current value of each current source may be adjustable. Accordingly, the linearization circuitry 90 may reduce a non-linear gain expansion or compression of the amplifier 89-1.

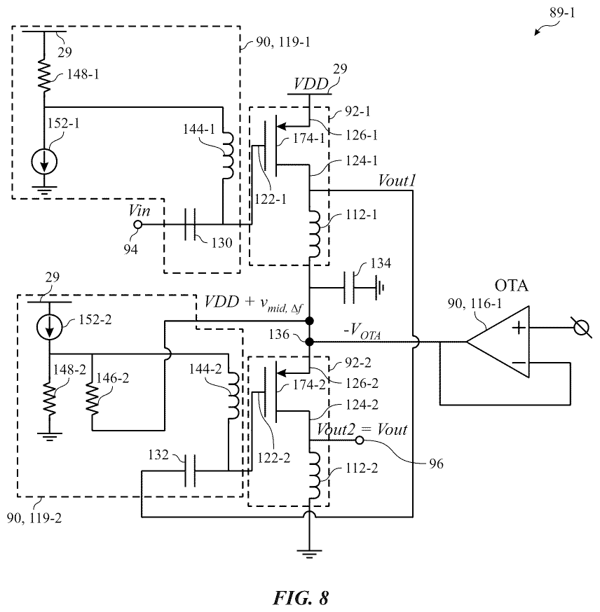

FIG. 8 is a schematic diagram of the amplifier 89-1 including the linearization circuitry 90 with the first amplifier stage 92-1 having a first P-channel device 174-1 forward-stacked with the second amplifier stage 92-2 having a second P-channel device 174-2, according to embodiments of the present disclosure. The first P-channel device 174-1 (e.g., the first switching device) and/or the second P-channel device 174-2 (e.g., the second switching device) may include any viable P-channel transistor such as a MOSFET, among other possibilities. The linearization circuitry 90 may include the first OTA 116-1 and a first P-channel gain correction circuit 119-1 coupled to the first control terminal 122-1 and the first bias output terminal 124-1 of the first amplifier stage 92-1.

It should be appreciated that in alternative or additional embodiments, the first amplifier stage 92-1 and/or the second amplifier stage 92-2 may include additional or alternative circuit components. For example, as mentioned above, the first amplifier stage 92-1 and/or the second amplifier stage 92-2 may include a transformer in lieu of or in addition to the first inductor 112-1 and the second inductor 112-2, respectively. Moreover, the first amplifier stage 92-1 and/or the second amplifier stage 92-2 may include one or more capacitors and/or resistors not shown for simplicity.

The first P-channel device 174-1 may have a gate terminal (e.g., the first control terminal 122-1), a source terminal (e.g., the first bias input terminal 126-1), and a drain terminal (e.g., the first bias output terminal 124-1). The second P-channel device 174-2 may have a gate terminal (e.g., the second control terminal 122-2), a source terminal (e.g., the second bias input terminal 126-2), and a drain terminal (e.g., the second bias output terminal 124-2). It should be appreciated that the first amplifier stage 92-1 and the second amplifier stage 92-2 may use any viable switching circuitry in lieu of or in addition to the first P-channel device 174-1 and/or the second P-channel device 174-2, respectively.

The gate terminal of the first P-channel device 174-1 may be coupled to the amplifier input terminal 94 via a first coupling capacitor 130. The gate terminal of the first P-channel device 174-1 may receive the modulated signal (e.g., input signal, Vᵢₙ) for amplification. The source terminal of the first P-channel device 174-1 may be coupled to the power source 29. The source terminal of the first P-channel device 174-1 may receive the bias signal (e.g., VDD) for amplifying the modulated signal. The first P-channel device 174-1 may amplify the modulated signal (e.g., the input signal, Vᵢₙ) based on a gain.

The first amplifier stage 92-1 may output the modulated signal (e.g., the first output signal, Vₒᵤₜ₁), as amplified by the first P-channel device 174-1, by the drain terminal of the first P-channel device 174-1. The drain terminal of the first P-channel device 174-1 may be coupled to the gate terminal of the second P-channel device 174-2 via a second coupling capacitor 132. As such, the gate terminal of the second P-channel device 174-2 may receive the modulated signal (e.g., the first output signal, Vₒᵤₜ₁), as amplified by the first P-channel device 174-1, from the drain terminal of the first P-channel device 174-1.

The first P-channel device 174-1 may output the bias signal by the respective drain terminal. The drain terminal of the first P-channel device 174-1 may be coupled to the source terminal of the second P-channel device 174-2 via the first inductor 112-1. As such, the source terminal of the second P-channel device 174-2 may receive the bias signal from the drain terminal of the first P-channel device 174-1 for amplifying the modulated signal. In some embodiments, the amplifier 89-1 may include a first bypass capacitor 134 coupling the first node 136 between the first inductor 112-1 and the second P-type device to the ground terminal. In some cases, the first bypass capacitor 134 may ground at least a portion of noises between the first inductor 112-1 and the first P-type device.

The second P-channel device 174-2 may receive the bias signal to amplify the modulated signal (e.g., the first output signal, Vₒᵤₜ₁) based on a gain. It should be appreciated that the first P-channel device 174-1 and the second P-channel device 174-2 may provide equal, substantially or relatively equal, or different gain values. The second amplifier stage 92-2 may output the modulated signal (e.g., the second output signal, the amplified signal, Vₒᵤₜ₂), as amplified by the first P-channel device 174-1 and the second P-channel device 174-2, by the drain terminal of the second P-channel device 174-2. In the depicted embodiment, the drain terminal of the second P-channel device 174-2 may be coupled to the amplifier output terminal 96 and to the ground terminal via the second inductor 112-2. As such, the amplifier 89-1 may output the second output signal (e.g., Vₒᵤₜ₂) as the amplified signal (e.g., Vₒᵤₜ) via the amplifier output terminal 96.

As discussed above, a frequency of the bias signal (e.g., VDD) may be zero (e.g., near zero, relatively zero) or below the frequency threshold. Moreover, the second amplifier stage 92-2 may receive the bias signal from the first amplifier stage 92-1 over the first node 136. As such, a frequency of the bias signal at the first node 136 between the first amplifier stage 92-1 and the second amplifier stage 92-2 may be zero (e.g., near zero, relatively zero) or below the frequency threshold. If not compensated for, in some cases, a non-linear gain expansion or compression of the first amplifier stage 92-1 and/or the second amplifier stage 92-2, among other things, may cause an undesired amplitude mis-match between the input signal (e.g., Vᵢₙ) and the amplified signal (e.g., Vₒᵤₜ) adversely affecting a signal quality of the amplified signal (e.g., Vₒᵤₜ) being generated and/or transmitted.

Similar to the example embodiments discussed above, the linearization circuitry 90 may reduce a voltage and/or current of the ripple signal and therefore improve the signal quality of the amplified signal carrying the outgoing data 60. The first OTA 116-1 may be coupled to the first node 136 between the first amplifier stage 92-1 and the second amplifier stage 92-2 to provide a low impedance ground path to signals having a frequency greater than or equal to than the frequency threshold. As such, the first OTA 116-1 may reduce a voltage and/or current of the ripple signal by grounding at least a portion of the ripple signal (e.g., V_{OTA}). In the depicted embodiment, a first P-channel gain correction circuit 119-1 may dampen, either compress or expand, an undesired gain expansion or compression of the first P-channel device 174-1 and/or the second P-channel device 174-2 to reduce a voltage and/or current of the ripple signal (e.g., a remaining portion of the ripple signal). Similar to the first N-channel gain correction circuit 118-1 discussed above, the first P-channel gain correction circuit 119-1 may include the first choke inductor 144-1, the first coupling capacitor 130, the first resistor 146-1, the second resistor 148-1, and the first current source 152-1.

In the depicted embodiment, the first choke inductor 144-1 may be coupled to the gate terminal of the first P-channel device 174-1 and the first coupling capacitor 130. The first resistor 146-1 may have a first terminal or port coupled to the first choke inductor 144-1, the second resistor 148-1, and the first current source 152-1, and a second terminal or port coupled to the first source terminal of the first P-channel device 174-1. The second resistor 148-1 may have a second terminal or port coupled to the first resistor 146-1, the first current source 152-1, and the first choke inductor 144-1, and a first terminal or port coupled to the power source 29. The first current source 152-1 may be coupled to the first resistor 146-1, the second resistor 148-1, and the first choke inductor 144-1 to receive a supply voltage (e.g., the bias signal). For example, the first current source 152-1 may be coupled to power source 29 via the second resistor 148-1. Moreover, the first current source 152-1 may output electrical current to a ground terminal or port.

A resistance values of the first resistor 146-1 and the second resistor 148-1, an inductance value of the first choke inductor 144-1, and an output current value of the first current source 152-1 may be selected to reduce a voltage or current of the ripple signal. Referring now to FIG. 15, the graph 160 illustrates example gain value changes of the amplifiers 89 based on resistance values of the first resistor 146-1 and the second resistor 148-1. For example, a greater resistance value of the second resistor 148-1 (or the first resistor 146-1) compared to the first resistor 146-1 (or the second resistor 148-1) may boot-strap the first P-channel device 174-1 to reduce a voltage and/or current of the ripple signal by linearizing (e.g., compressing, reducing) an undesired gain expansion of the first P-channel device 174-1. Moreover, a greater resistance value of the first resistor 146-1 (or the second resistor 148-1) compared to the second resistor 148-1 (or the first resistor 146-1) may reduce the voltage and/or current of the ripple signal by linearizing (e.g., expanding, increasing) an undesired gain compression of the first P-channel device 174-1. Accordingly, the linearization circuitry 90 may reduce a non-linear gain expansion or compression of the amplifier 89-1.

Referring back to FIG. 8, the linearization circuitry 90 may include a second P-channel gain correction circuit 119-2 to reduce a non-linear gain expansion or compression of the amplifier 89-1. The second P-channel gain correction circuit 119-2 may be coupled to a second control terminal or port 122-2 and a second bias output terminal or port 124-2 of the second P-channel device 110-2. The second P-channel gain correction circuit 119-2 may include a first choke inductor 144-2, the second coupling capacitor 132, a first resistor 146-2, a second resistor 148-2, and a first current source 152-2.

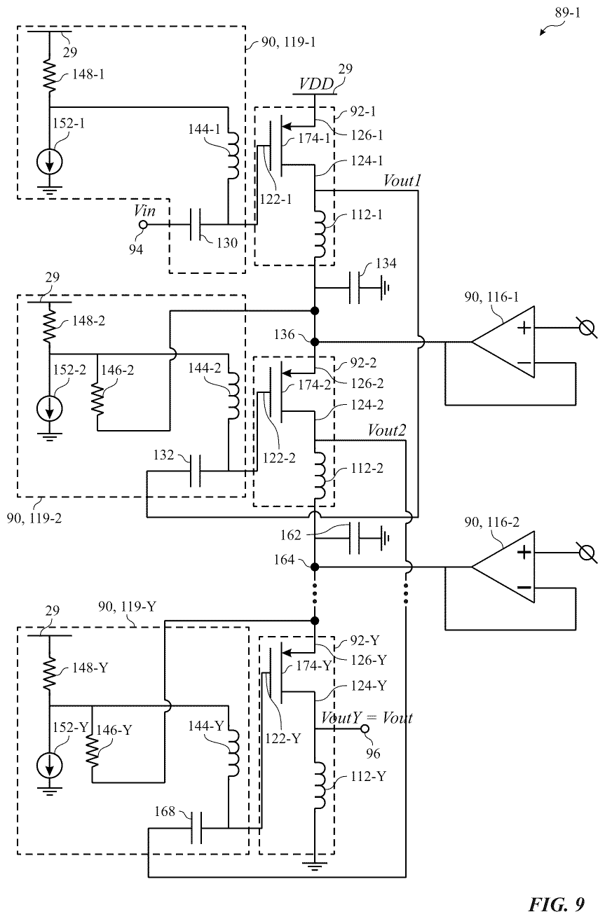

FIG. 9 is a schematic diagram of the amplifier 89-1 including the linearization circuitry 90 and the first amplifier stage 92-1 having the first P-channel device 174-1 forward-stacked with the second amplifier stage 92-2 having the second P-channel device 174-2 and at least the Yth amplifier stage 92-Y having a Yth P-channel device 174-Y, according to embodiments of the present disclosure. Each amplifier stage 92 may include a respective P-channel device and a respective inductor. For example, in the depicted embodiment, the first amplifier stage 92-1 may include the first inductor 112-1 and the first P-channel device 174-1, the second amplifier stage 92-2 may include the second inductor 112-2 and the second P-channel device 174-2, and the Yth amplifier stage 92-Y may include the Yth inductor 112-Y and a Yth P-channel device 174-Y (e.g., the Yth switching device).

It should be appreciated that the amplifier 89-1 may include any viable number of amplifier stages 92 (e.g., 2, 3, 4, 5, and so on, N). Each P-channel device may include any viable P-channel transistor such as a MOSFET, among other possibilities. Moreover, the first amplifier stage 92-1 and/or the second amplifier stage 92-2 may include additional or alternative circuit components. For example, each amplifier stage 92 may include one or more N-channel devices 110 in lieu or in addition to the respective P-channel device and/or a transformer in lieu of or in addition to the respective inductor.

The first P-channel device 174-1 may have the gate terminal (e.g., the first control terminal 122-1), the drain terminal (e.g., the first bias input terminal 126-1), and the source terminal (e.g., the first bias output terminal 124-1). The second P-channel device 174-2 may have the gate terminal (e.g., the second control terminal 122-2), a drain terminal (e.g., the second bias input terminal 126-2), and the source terminal (e.g., the second bias output terminal 124-2). Similarly, the Yth P-channel device 174-Y may have a gate terminal (e.g., a Yth control terminal 122-Y), a drain terminal (e.g., a Yth bias input terminal 126-Y), and a source terminal (e.g., a Yth bias output terminal 124-Y). It should be appreciated that each amplifier stage 92 may use any viable switching circuitry in lieu of or in addition to the respective P-channel devices 174.

In the depicted embodiment, the first bias input terminal 126-1 of the first P-channel device 174-1 may be coupled to the power source 29 via the first inductor 112-1. Moreover, the first bias output terminal 124-1 of the first P-channel device 174-1 may be coupled to the second bias input terminal 126-2 of the second P-channel device 174-2 via the second inductor 112-2. As such, the first P-channel device 174-1 may receive the bias signal (e.g., VDD) from the power source 29 and output (e.g., share) the bias signal to the second P-channel device 174-2. Similarly, the second bias output terminal 124-2 of the second P-channel device 174-2 may be coupled to a subsequent bias input terminal of a subsequent P-channel device of a subsequent P-channel device via a subsequent inductor.

The second bias output terminal 124-2 may be coupled to the Yth bias input terminal 126-Y of the Yth P-channel device 174-Y via the Yth inductor 112-Y. As such, the bias input terminal of the subsequent P-channel device (e.g., the Yth P-channel device 174-Y) may receive the bias signal. That is, the P-channel device of each amplifier stage 92 may share the bias signal with a subsequent amplifier stage. As mentioned above, the amplifier 89-1 may include any viable number of amplifier stages 92. Accordingly, the second bias output terminal 124-2 may be coupled to any number of additional P-channel devices not shown before the bias signal is shared with a last P-channel device (e.g., the Yth P-channel device 174-Y).

The amplifier stages 92 are cascaded such that each amplifier stage 92 may output a respective output signal to a subsequent amplifier stage. The first control terminal 122-1 of the first P-channel device 174-1 may be coupled to the amplifier input terminal 94 via the first coupling capacitor 130 to receive the modulated signal (e.g., input signal, Vᵢₙ). The first P-channel device 174-1 may amplify the modulated signal (e.g., the input signal, Vᵢₙ) based on a gain. The first amplifier stage 92-1 may output the modulated signal (e.g., the first output signal, Vₒᵤₜ₁), as amplified by the first P-channel device 174-1, by the first bias output terminal 124-1 of the first P-channel device 174-1.

The first bias output terminal 124-1 of the first P-channel device 174-1 may be coupled to the second control terminal 122-2 of the second P-channel device 174-2 via the second coupling capacitor 132. As such, the second P-channel device 174-2 may receive the modulated signal (e.g., the first output signal, Vₒᵤₜ₁), as amplified by the first P-channel device 174-1. Similarly, the second amplifier stage 92-2 may output the modulated signal (e.g., the second output signal, Vₒᵤₜ₂), as amplified by the first P-channel device 174-1 and the second P-channel device 174-2, by the second bias output terminal 124-2 of the second P-channel device 174-2.

The second bias output terminal 124-2 of the second P-channel device 174-2 may be coupled to a control terminal of a subsequent P-channel device. In the depicted embodiment, the second bias output terminal 124-2 of the second P-channel device 174-2 may be coupled to the Yth control terminal 122-Y of the Yth P-channel device 174-Y via a Yth coupling capacitor 168. As such, the Yth P-channel device 174-Y may receive the modulated signal (e.g., the second output signal, Vₒᵤₜ₂), as amplified by the first P-channel device 174-1 and the second P-channel device 174-2. The Yth bias output terminal 124-Y of the Yth P-channel device 174-Y may be coupled to the amplifier output terminal 96. Accordingly, the amplifier 89-1 may output the Yth output signal (e.g., V_{outY}) as the amplified signal (e.g., Vₒᵤₜ) via the amplifier output terminal 96. As mentioned above, the amplifier 89-1 may include any viable number of amplifier stages 92 (e.g., 2, 3, 4, 5, and so on, Y).

It should be appreciated that each P-channel device may amplify the modulated signal based on equal, substantially or relatively equal, or different gain values. In some embodiments, the amplifier 89-1 may include the first bypass capacitor 134 and the second bypass capacitor 162 coupling the second node 164 between the second P-channel device 174-2 and the Yth inductor 112-Y to the ground terminal. In some cases, the second bypass capacitor 162 may ground at least a portion of noises between the second P-channel device 174-2 and the Yth inductor 112-Y.

In the depicted embodiment, the linearization circuitry 90 may include the first OTA 116-1, the second OTA 116-2, the Yth OTA 116-Y, the first P-channel gain correction circuit 119-1, the second P-channel gain correction circuit 119-2, and the Yth P-channel gain correction circuit 119-Y. In some cases, the linearization circuitry 90 may reduce a voltage and/or current of one or more undesired ripple signals, for example, on the first node 136 and/or the second node 164. As such, the linearization circuitry 90 may improve the signal quality of the amplified signal carrying the outgoing data 60.

The first OTA 116-1 may be coupled to the first bias output terminal 124-1 of the first amplifier stage 92-1 and the second bias output terminal 124-2 of the second amplifier stage 92-2. The second OTA 116-2 may be coupled to the second bias output terminal 124-2 of the second amplifier stage 92-2 and the Yth bias output terminal 124-Y of the Yth amplifier stage 92-Y. It should be appreciated that the linearization circuitry 90 may include one or more additional OTAs, for example, coupled to a bias input terminal and/or a bias output terminal of one or more additional amplifier stages 92 not shown for simplicity.

Each OTA 116 may provide a low impedance ground path to signals having a frequency greater than or equal to the frequency threshold to reduce a voltage and/or current of an undesired ripple signal. As discussed above, the OTAs 116 may draw at least a portion of electrical currents of an undesired ripple signal to reduce a voltage and/or power of the undesired ripple signal. Accordingly, the OTAs 116 may reduce undesired (e.g., non-linear) behavior of amplifier 89-1 and/or improve the signal quality of the amplified signal carrying the outgoing data 60.

The P-channel gain correction circuits 119 may be coupled to a control terminal and/or a bias output terminal of a respective amplifier stage. In some embodiments, each P-channel gain correction circuit 119 may include a choke inductor 144, a coupling capacitor (e.g., the first coupling capacitor 130, the second coupling capacitor 132, the Yth coupling capacitor 168), a first resistor (e.g., the first resistor 146-1, 146-2, and/or 146-Y), a second resistor (e.g., the second resistor 148-1, 148-2, and/or 148-Y), and a current source 152 (e.g., the current sources 152-1, 152-2, and 152-Y). In the depicted embodiment, the Yth P-channel gain correction circuit 119-Y may not include a respective first resistor 146. Alternatively or additionally, the Yth P-channel gain correction circuit 119-Y may include a respective first resistor 146 coupled to the Yth bias output terminal 124-Y of the Yth P-channel device 174-Y.

It should be appreciated that the linearization circuitry 90 may include one or more additional P-channel gain correction circuits, for example, coupled to a control terminal and a bias output terminal of one or more additional P-channel device (not shown). Each P-channel gain correction circuit 119 may reduce a voltage or current of an undesired ripple signal. Accordingly, the linearization circuitry 90, including the OTAs 116 and the P-channel gain correction circuits 119, may reduce a non-linear gain expansion or compression of the amplifier 89-1.

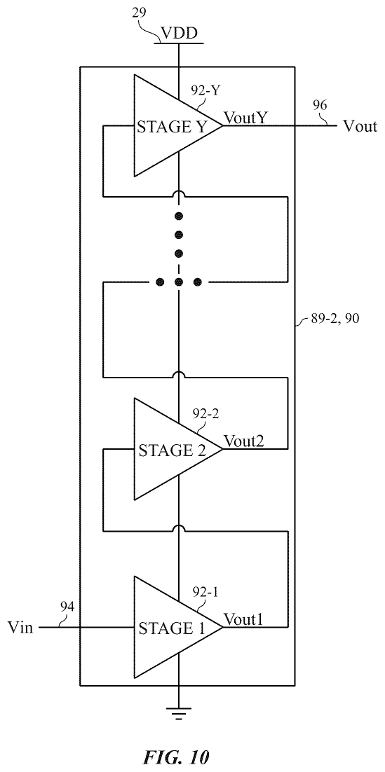

FIG. 10 is a block diagram of an amplifier 89-2 including the linearization circuitry 90 and multiple (e.g., 2, 3, 4, 5, or more) cascaded amplifier stages 92 where the first amplifier stage 92-1 outputs the output signal of the amplifier 89-2, according to embodiments of the present disclosure. In some embodiments, the amplifier 89-2 may correspond to an embodiment of the power amplifier 66 of FIG. 3. In alternative or additional embodiments, the amplifier 89-2 may correspond to an embodiment of the low noise amplifier 82 of FIG. 4.

The amplifier 89-2 may include any number of amplifier stages 92 including the first amplifier stage 92-1, the second amplifier stage 92-2, and the Yth amplifier stage 92-Y discussed above. Each amplifier stage 92 may amplify an input signal to generate a respective output signal (e.g., Vₒᵤₜ₁, Vₒᵤₜ₂, V_{outY}, among others) based on a gain. Moreover, the amplifier stages 92 are cascaded such that each amplifier stage 92 may provide the respective output signal to a subsequent amplifier stage.

For example, the amplifier 89-2 may receive the modulated signal (e.g., the input signal, Vᵢₙ) carrying the outgoing data 60 to generate the amplified signal (e.g., Vₒᵤₜ) for transmission. The amplifier input terminal 94 may be coupled to an input terminal of port of the first amplifier stage 92-1. The first amplifier stage 92-1 may amplify the modulated signal based on a gain. In some cases, the amplifier 89-2 may output the first output signal (e.g., Vₒᵤₜ₁) as the amplified signal (e.g., Vₒᵤₜ) via an amplifier output terminal 96. Alternatively or additionally, the second amplifier stage 92-2 may receive the first output signal (e.g., Vₒᵤₜ₁) of the first amplifier stage 92-1.

The second amplifier stage 92-2 may amplify the first output signal based on a gain. That is, the second amplifier stage 92-2 may amplify the modulated signal, as amplified by the first amplifier stage 92-1, based on a gain to generate the second output signal (e.g., Vₒᵤₜ₂). In some cases, the amplifier 89-2 may output the second output signal (e.g., Vₒᵤₜ₂) as the amplified signal (e.g., Vₒᵤₜ) via the amplifier output terminal 96. Alternatively or additionally, the second amplifier stage 92-2 may output the second output signal (e.g., Vₒᵤₜ₂) to a subsequent amplifier stage coupled thereto (e.g., the Yth amplifier stage 92-Y) for further amplification of the modulated signal.

In different embodiments, the amplifier 89-2 may include a different number of amplifier stages 92 for amplifying the modulated signal. Moreover, as discussed above, the modulated signal may carry (e.g., include) the outgoing data 60. As such, the amplifier 89-2 may output the amplified signal carrying the outgoing data 60 with an amplified voltage swing based on a total gain of the amplifier stages 92. The total gain of the amplifier stages 92 may correspond to a cumulative gain of each of the amplifier stages 92. It should be appreciated that the amplifier stages 92 may have equal, substantially or relatively equal, or different gain values.

With the foregoing in mind, the amplifier stages 92 may receive (e.g., share) a bias signal (e.g., VDD) from the power source 29 discussed above for amplifying the modulated signal. The Yth amplifier stage 92-Y may provide (e.g., output) the bias signal to the N-1th amplifier stage (e.g., the second amplifier stage 92-2). As mentioned above, the amplifier 89-2 may include any number of amplifier stages 92 including the first amplifier stage 92-1, the second amplifier stage 92-2, and the Yth amplifier stage 92-Y. Similarly, the N-1th amplifier stage (e.g., the second amplifier stage 92-2) may provide (e.g., output) the bias signal to a previous amplifier stage (e.g., the first amplifier stage 92-1). As such, the amplifier 89-2 may have a reduced electrical power consumption based on stacking the amplifier stages 92 and sharing the bias signal (e.g., instead of each amplifier stage 92 receiving a separate bias signal).

The amplifier 89-2 may include the linearization circuitry 90 to improve linearity of the total gain of the amplifier 89-2, as will be appreciated. For example, the linearization circuitry 90 may increase a headroom voltage between the bias signal and output signals of the first amplifier stage 92-1, the second amplifier stage 92-2, and so on. Alternatively or additionally, the linearization circuitry 90 may decrease an electrical current consumption of the first amplifier stage 92-1 and/or the second amplifier stage 92-2.

In some cases, the linearization circuitry 90 may reduce non-linearities of the bias signal received by one or more of the stacked amplifier stages 92. For example, the linearization circuitry 90 may reduce a non-linear gain expansion or compression of one or more of the amplifier stages 92 adversely affecting (e.g., interacting with) the shared bias signal between the amplifier stages 92. Accordingly, the linearization circuitry 90 may improve a signal quality and/or reduce a degradation and/or distortion of the amplified signal (e.g., Vₒᵤₜ) carrying the outgoing data 60.

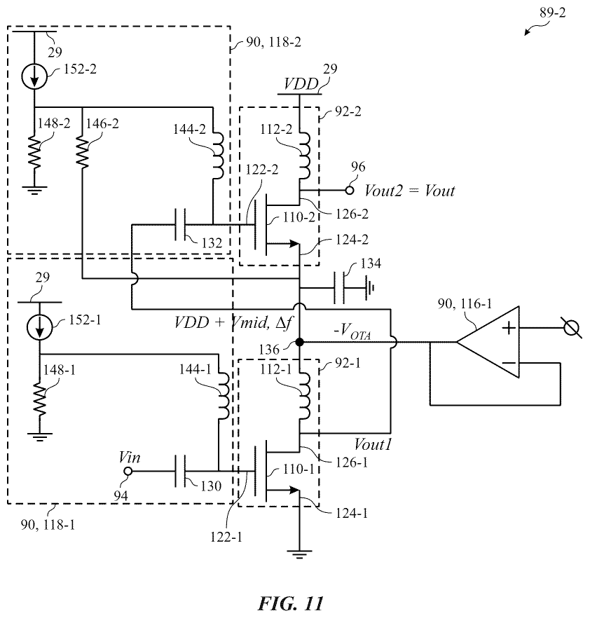

FIG. 11 is a schematic diagram of the amplifier 89-2 including the linearization circuitry 90 with the first amplifier stage 92-1 having the first N-channel device 110-1 forward-stacked with the second amplifier stage 92-2 having the second N-channel device 110-2, according to embodiments of the present disclosure. The first amplifier stage 92-1 may include the first inductor 112-1 and the first N-channel device 110-1 (e.g., the first switching device) and the second amplifier stage 92-2 (e.g., the second switching device) may include the second inductor 112-2 and the second N-channel device 110-2. The linearization circuitry 90 may include a first OTA 116-1 and a second N-channel gain correction circuit 118-2 of the second amplifier stage 92-2. The second N-channel gain correction circuit 118-2 may be coupled to the second control terminal 122-2 and the second bias output terminal 124-2 of the second N-channel device 110-2. In some embodiments, the linearization circuitry 90 may additionally or alternatively include a first filter coupled to the first control terminal 122-1 and the first bias output terminal 124-1 of the first amplifier stage 92-1.

It should be appreciated that the first amplifier stage 92-1 and/or the second amplifier stage 92-2 may include one or more P-channel devices 174 in lieu or in addition to the first N-channel device 110-1 and the second N-channel device 110-2, respectively. Moreover, in alternative or additional embodiments, the first amplifier stage 92-1 and/or the second amplifier stage 92-2 may include additional or alternative circuit components. For example, the first amplifier stage 92-1 and/or the second amplifier stage 92-2 may include a transformer in lieu of or in addition to the first inductor 112-1 and the second inductor 112-2, respectively. Moreover, the first amplifier stage 92-1 and/or the second amplifier stage 92-2 may include one or more capacitors and/or resistors not shown for simplicity.

The first N-channel device 110-1 and/or the second N-channel device 110-2 may include any viable N-channel transistor such as a MOSFET, among other possibilities. As mentioned above, the first N-channel device 110-1 may have the gate terminal (e.g., the first control terminal 122-1), the drain terminal (e.g., the first bias input terminal 126-1), and the source terminal (e.g., the first bias output terminal 124-1). Moreover, the second N-channel device 110-2 may have the gate terminal (e.g., the second control terminal 122-2), the drain terminal (e.g., the second bias input terminal 126-2), and the source terminal (e.g., the second bias output terminal 124-2). It should be appreciated that the first amplifier stage 92-1 and the second amplifier stage 92-2 may use any viable switching circuitry in lieu of or in addition to the first N-channel device 110-1 and/or the second N-channel device 110-2, respectively.

The drain terminal of the second N-channel device 110-2 may be coupled to the power source 29 via the second inductor 112-2. As such, the drain terminal of the second N-channel device 110-2 may receive the bias signal (e.g., VDD) for amplifying the modulated signal. Moreover, the source terminal of the second N-channel device 110-2 may be coupled to the drain terminal of the first N-channel device 110-1 via the first inductor 112-1. The second N-channel device 110-2 may output the bias signal by the respective source terminal. As such, the drain terminal of the first N-channel device 110-1 may receive the bias signal for amplifying the modulated signal. In some embodiments, the amplifier 89-2 may include a first bypass capacitor 134 coupling the first node 136 between the second N-channel device 110-2 and the first inductor 112-1 to the ground terminal. In some cases, the first bypass capacitor 134 may ground at least a portion of noises between the first amplifier stage 92-1 and the second amplifier stage 92-2.

The gate terminal of the first N-channel device 110-1 may be coupled to the amplifier input terminal 94 via a first coupling capacitor 130. The gate terminal of the first N-channel device 110-1 may receive the modulated signal (e.g., input signal, Vᵢₙ) for amplification. The first N-channel device 110-1 may amplify the modulated signal (e.g., the input signal, Vᵢₙ) based on a gain when receiving the bias signal. The first amplifier stage 92-1 may output the modulated signal (e.g., the first output signal, Vₒᵤₜ₁), as amplified by the first N-channel device 110-1, by the drain terminal of the first N-channel device 110-1. The drain terminal of the first N-channel device 110-1 may be coupled to the gate terminal of the second N-channel device 110-2 via a second coupling capacitor 132. As such, the gate terminal of the second N-channel device 110-2 may receive the modulated signal (e.g., the first output signal, Vₒᵤₜ₁), as amplified by the first N-channel device 110-1.

The second N-channel device 110-2 may amplify the input signal (e.g., the first output signal, Vₒᵤₜ₁) based on a gain when receiving the bias signal. It should be appreciated that the first N-channel device 110-1 and the second N-channel device 110-2 may provide equal, substantially or relatively equal, or different gain values. The second amplifier stage 92-2 may output the modulated signal (e.g., the second output signal, the amplified signal, Vₒᵤₜ₂), as amplified by the first N-channel device 110-1 and the second N-channel device 110-2, by the drain terminal of the second N-channel device 110-2. In the depicted embodiment, the drain terminal of the second N-channel device 110-2 may be coupled to the amplifier output terminal 96. As such, the amplifier 89-2 may output the second output signal (e.g., Vₒᵤₜ₂) as the amplified signal (e.g., Vₒᵤₜ) via the amplifier output terminal 96.

The second amplifier stage 92-2 may receive the bias signal, having a frequency of zero (e.g., near zero, relatively zero) or below the frequency threshold, from the first amplifier stage 92-1 over the first node 136. As such, a frequency of the bias signal at the first node 136 between the first amplifier stage 92-1 and the second amplifier stage 92-2 may be zero (e.g., near zero, relatively zero) or below the frequency threshold. If not compensated for, in some cases, a non-linear gain expansion or compression of the first amplifier stage 92-1 and/or the second amplifier stage 92-2, among other things, may cause an undesired amplitude mis-match between the input signal (e.g., Vᵢₙ) and the amplified signal (e.g., Vₒᵤₜ) adversely affecting a signal quality of the amplified signal (e.g., Vₒᵤₜ) being generated and/or transmitted.

The linearization circuitry 90 may reduce a voltage and/or current of the ripple signal and therefore improve the signal quality of the amplified signal carrying the outgoing data 60. The linearization circuitry 90 may include the OTA and the second N-channel gain correction circuit 118-2 coupled to the first node 136 between the first amplifier stage 92-1 and the second amplifier stage 92-2. The OTA may provide a low impedance ground path to signals having a frequency greater than or equal to the frequency threshold. The OTA may reduce a voltage and/or current of the ripple signal by grounding at least a portion of the ripple signal (e.g., V_{OTA}). Moreover, the second N-channel gain correction circuit 118-2 may reduce a voltage or current of a remaining portion of the ripple signal.

Similar to the example embodiments discussed above, the first input terminal (e.g., the positive input terminal) of the first OTA 116-1 may be coupled to the controlled voltage source. The second input terminal (e.g., the negative input terminal) of the first OTA 116-1 may be coupled to the OTA output terminal. Moreover, the OTA output terminal may be coupled to the first node 136 between the first amplifier stage 92-1 and the second amplifier stage 92-2. The transconductance of the first OTA 116-1 and the controlled voltage provided to the first OTA 116-1 input terminal may be selected such that the OTA output terminal may provide a relatively low impedance less than the impedance threshold to signals having a frequency range including that of the ripple signal. Accordingly, the first OTA 116-1 may draw at least a portion of electrical currents of the first node 136 and reduce a voltage and/or power of the ripple signal to reduce undesired (e.g., non-linear) behavior of amplifier 89-2.

The second N-channel gain correction circuit 118-2 may include a second choke inductor 144-2, a second coupling capacitor 132, the first resistor 146-2, the second resistor 148-2, and the second current source 152-2. The second choke inductor 144-2 may be coupled to the second gate terminal and the second coupling capacitor 132. The first resistor 146-2 may have a first terminal coupled to the second choke inductor 144-2, the second resistor 148-2, and the second current source 152-2, and a second terminal coupled to the first source terminal of the second N-channel device 110-2. The second resistor 148-2 may have a first terminal coupled to the first resistor 146-2, the second current source 152-2, and the second choke inductor 144-2, and a second terminal coupled to the ground terminal. The second current source 152-2 may be coupled to the power source 29 to receive a supply voltage (e.g., the bias signal). Moreover, the second current source 152-2 may output electrical current to the first resistor 146-2, the second resistor 148-2, and the second choke inductor 144-2.

The resistance values of the first resistor 146-2 and the second resistor 148-2, the inductance value of the second choke inductor 144-2, and the output current value of the second current source 152-2 may be selected to reduce a voltage or current of the ripple signal. Referring now to FIG. 15, the graph 160 illustrates example gain value changes of the amplifiers 89 based on resistance values of the first resistor 146-1 and the second resistor 148-1. For example, a greater resistance value of the second resistor 148-2 compared to the first resistor 146-2 may boot-strap the second N-channel device 110-2 to reduce a voltage and/or current of the ripple signal by linearizing (e.g., compressing) an undesired gain expansion of the second N-channel device 110-2. Moreover, a greater resistance value of the first resistor 146-2 compared to the second resistor 148-2 may reduce the voltage and/or current of the ripple signal by linearizing (e.g., expanding) an undesired gain compression of the second N-channel device 110-2.

Referring back to FIG. 11, the resistance values of the first resistor 146-2 and the second resistor 148-2, the inductance value of the second choke inductor 144-2, and the output current value of the second current source 152-2 may be selected during manufacturing of the amplifier 89-2. In alternative or additional embodiments, a processor and/or controller coupled to the amplifier 89-2, such as the processor 12 discussed above, may dynamically select (e.g., adjust) such values of the components of the second N-channel gain correction circuit 118-2. For example, the resistance value of the first resistor 146-2 and/or the second resistor 148-2, the inductance value of the second choke inductor 144-2, and/or the output current value of the second current source 152-2 may be adjustable. Accordingly, the linearization circuitry 90 may reduce a non-linear gain expansion or compression of the amplifier 89-2.

Similarly, the linearization circuitry 90 may include a first N-channel gain correction circuit 118-1 to reduce a non-linear gain expansion or compression of the amplifier 89-2. The first N-channel gain correction circuit 118-1 may be coupled to a first control terminal or port 122-1 and a first bias output terminal or port 124-1 of the first N-channel device 110-1. The first N-channel gain correction circuit 118-1 may include a first choke inductor 144-1, the first coupling capacitor 130, a first resistor 146-1, a first resistor 148-1, and a first current source 152-1.

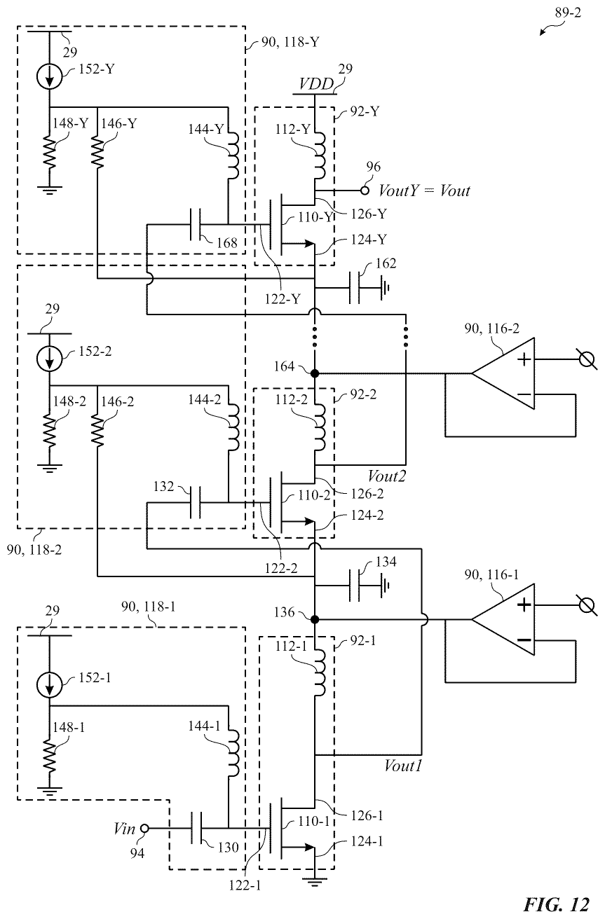

FIG. 12 is a schematic diagram of the amplifier 89-2 including the linearization circuitry 90 and the first amplifier stage 92-1 having the first N-channel device 110-1 forward-stacked with the second amplifier stage 92-2 having the second N-channel device 110-2 and at least the Yth amplifier stage 92-Y having a Yth N-channel device 110-Y, according to embodiments of the present disclosure. Each amplifier stage 92 may include a respective N-channel device and a respective inductor. For example, in the depicted embodiment, the first amplifier stage 92-1 may include the first inductor 112-1 and the first N-channel device 110-1, the second amplifier stage 92-2 may include the second inductor 112-2 and the second N-channel device 110-2, and the Yth amplifier stage 92-Y may include the Yth inductor 112-Y and a Yth N-channel device 110-Y (e.g., the Yth switching device).

It should be appreciated that the amplifier 89-2 may include any viable number of amplifier stages 92 (e.g., 2, 3, 4, 5, and so on, N). Each N-channel device may include any viable N-channel transistor such as a MOSFET, among other possibilities. Moreover, the first amplifier stage 92-1 and/or the second amplifier stage 92-2 may include additional or alternative circuit components. For example, each amplifier stage 92 may include one or more P-channel devices 174 in lieu or in addition to the respective N-channel device and/or a transformer in lieu of or in addition to the respective inductor.

The first N-channel device 110-1 may have the gate terminal (e.g., the first control terminal 122-1), the drain terminal (e.g., the first bias input terminal 126-1), and the source terminal (e.g., the first bias output terminal 124-1). The second N-channel device 110-2 may have the gate terminal (e.g., the second control terminal 122-2), the drain terminal (e.g., the second bias input terminal 126-2), and the source terminal (e.g., the second bias output terminal 124-2). Similarly, the Yth N-channel device 110-Y may have a gate terminal (e.g., a Yth control terminal 122-Y), a drain terminal (e.g., a Yth bias input terminal 126-Y), and a source terminal (e.g., a Yth bias output terminal 124-Y). It should be appreciated that each amplifier stage 92 may use any viable switching circuitry in lieu of or in addition to the respective N-channel devices 110.

In the depicted embodiment, the first bias input terminal 126-1 of the Yth N-channel device 110-Y may be coupled to the power source 29 via the Yth inductor 112-Y. Moreover, the Yth bias output terminal 124-Y of the Yth N-channel device 110-Y may be coupled to a bias input terminal of a previous N-channel device (e.g., the second bias input terminal 126-2 of the second N-channel device 110-2) via a previous inductor. In the depicted embodiment, the Yth bias output terminal 124-Y may be coupled to the second bias input terminal 126-2 of the second N-channel device 110-2 via the second inductor 112-2. As such, the Yth N-channel device 110-Y may receive the bias signal (e.g., VDD) from the power source 29 and output (e.g., share) the bias signal to the second N-channel device 110-2.

The second bias output terminal 124-2 of the second N-channel device 110-2 may be coupled to the first bias input terminal 126-1 of the first N-channel device 110-1 via the first inductor 112-1. As such, the first bias input terminal 126-1 of the first N-channel device 110-1 may receive the bias signal. That is, the N-channel device of each amplifier stage 92 may share the bias signal with a previous amplifier stage. As mentioned above, the amplifier 89-2 may include any viable number of amplifier stages 92. Accordingly, the Yth bias output terminal 124-Y may be coupled to any number of additional intermediary N-channel devices not shown before the bias signal is shared with the second N-channel device 110-2.

The amplifier stages 92 are cascaded such that each amplifier stage 92 may output a respective output signal to a subsequent amplifier stage. The first control terminal 122-1 of the first N-channel device 110-1 may be coupled to the amplifier input terminal 94 via the first coupling capacitor 130 to receive the modulated signal (e.g., input signal, Vᵢₙ). The first N-channel device 110-1 may amplify the input signal (e.g., Vᵢₙ) based on a gain. The first amplifier stage 92-1 may output the modulated signal (e.g., the first output signal, Vₒᵤₜ₁), as amplified by the first N-channel device 110-1, by the first bias input terminal 126-1 of the first N-channel device 110-1.

The first bias input terminal 126-1 of the first N-channel device 110-1 may be coupled to the second control terminal 122-2 of the second N-channel device 110-2 via the second coupling capacitor 132. As such, the second N-channel device 110-2 may receive the modulated signal (e.g., the first output signal, Vₒᵤₜ₁), as amplified by the first N-channel device 110-1. Similarly, the second amplifier stage 92-2 may output the modulated signal (e.g., the second output signal, Vₒᵤₜ₂), as amplified by the first N-channel device 110-1 and the second N-channel device 110-2, by the second bias input terminal 126-2 of the second N-channel device 110-2.

The second bias input terminal 126-2 of the second N-channel device 110-2 may be coupled to a control terminal of a subsequent N-channel device. In the depicted embodiment, the second bias input terminal 126-2 of the second N-channel device 110-2 may be coupled to the Yth control terminal 122-Y of the Yth N-channel device 110-Y via a Yth coupling capacitor 168. As such, the Yth N-channel device 110-Y may receive the modulated signal (e.g., the second output signal, Vₒᵤₜ₂), as amplified by the first N-channel device 110-1 the second N-channel device 110-2. The Yth bias input terminal 126-Y of the Yth N-channel device 110-Y may be coupled to the amplifier output terminal 96. Accordingly, the amplifier 89-2 may output the Yth output signal (e.g., V_{outY}) as the amplified signal (e.g., Vₒᵤₜ) via the amplifier output terminal 96. As mentioned above, the amplifier 89-2 may include any viable number of amplifier stages 92.

It should be appreciated that each N-channel device may amplify the input signal based on equal, substantially or relatively equal, or different gain values. In some embodiments, the amplifier 89-2 may include the first bypass capacitor 134 and a second bypass capacitor 162 coupling a second node 164 between the second N-channel device 110-2 and the Yth inductor 112-Y to the ground terminal. In some cases, the second bypass capacitor 162 may ground at least a portion of noises between the second N-channel device 110-2 and the Yth inductor 112-Y.

In the depicted embodiment, the linearization circuitry 90 may include the first OTA 116-1, the second OTA 116-2, the Yth OTA 116-Y, the first N-channel gain correction circuit 118-1, the second N-channel gain correction circuit 118-2, and the Yth N-channel gain correction circuit 118-Y. In some cases, the linearization circuitry 90 may reduce a voltage and/or current of one or more undesired ripple signals, for example, on the first node 136 and/or the second node 164. As such, the linearization circuitry 90 may improve the signal quality of the amplified signal carrying the outgoing data 60.

The first OTA 116-1 may be coupled to the first bias output terminal 124-1 of the first amplifier stage 92-1 and the second bias output terminal 124-2 of the second amplifier stage 92-2. The second OTA 116-2 may be coupled to the second bias output terminal 124-2 of the second amplifier stage 92-2 and the Yth bias output terminal 124-Y of the Yth amplifier stage 92-Y. It should be appreciated that the linearization circuitry 90 may include one or more additional OTAs, for example, coupled to a bias input terminal and/or a bias output terminal of one or more additional amplifier stages 92 not shown for simplicity.

Each OTA 116 may provide a low impedance ground path to signals having a frequency greater than or equal to the frequency threshold to reduce a voltage and/or current of an undesired ripple signal. As discussed above, the OTAs 116 may draw at least a portion of electrical currents of an undesired ripple signal to reduce a voltage and/or power of the undesired ripple signal. Accordingly, the OTAs 116 may reduce undesired (e.g., non-linear) behavior of amplifier 89-2 and/or improve the signal quality of the amplified signal carrying the outgoing data 60.

The N-channel gain correction circuits 118 may be coupled to a control terminal and/or a bias output terminal of a respective amplifier stage. In some embodiments, each N-channel gain correction circuit 118 may include a choke inductor 144, a coupling capacitor (e.g., the first coupling capacitor 130, the second coupling capacitor 132, the Yth coupling capacitor 168), a first resistor 146 (e.g., the first resistor 146-1, 146-2, and/or 146-Y), a second resistor 148 (e.g., the second resistor 148-1, 148-2, and/or 148-Y), and a current source 152 (e.g., the current sources 152-1, 152-2, and 152-Y). In the depicted embodiment, the first N-channel gain correction circuit 118-1 may not include a respective first resistor 146. Alternatively or additionally, the first N-channel gain correction circuit 118-1 may include a respective first resistor 146 coupled to the first bias output terminal 124-1 of the first N-channel device 110-1.

It should be appreciated that the linearization circuitry 90 may include one or more additional N-channel gain correction circuits 118, for example, coupled to a control terminal and a bias output terminal of one or more additional N-channel device (not shown). Each N-channel gain correction circuit 118 may reduce a voltage or current of an undesired ripple signal. Accordingly, the linearization circuitry 90, including the OTAs 116 and the N-channel gain correction circuits 118, may reduce a non-linear gain expansion or compression of the amplifier 89-2.

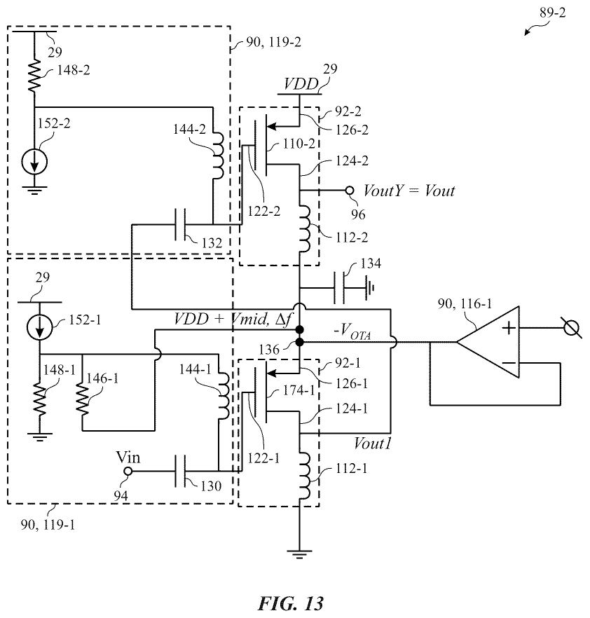

FIG. 13 is a schematic diagram of the amplifier 89-2 including the linearization circuitry 90 with the first amplifier stage 92-1 having the first P-channel device 174-1 reverse-stacked with the second amplifier stage 92-2 having the second P-channel device 174-2, according to embodiments of the present disclosure. It should be appreciated that in alternative or additional embodiments, the first amplifier stage 92-1 and/or the second amplifier stage 92-2 may include additional or alternative circuit components. For example, as mentioned above, the first amplifier stage 92-1 and/or the second amplifier stage 92-2 may include a transformer in lieu of or in addition to the first inductor 112-1 and the second inductor 112-2, respectively. Moreover, the first amplifier stage 92-1 and/or the second amplifier stage 92-2 may include one or more capacitors and/or resistors not shown for simplicity.

The first P-channel device 174-1 (e.g., the first switching device) and/or the second P-channel device 174-2 (e.g., the second switching device) may include any viable P-channel transistor such as a MOSFET, among other possibilities. As mentioned above, the first P-channel device 174-1 may have the gate terminal (e.g., the first control terminal 122-1), the source terminal (e.g., the first bias input terminal 126-1), and the drain terminal (e.g., the first bias output terminal 124-1). Moreover, the second P-channel device 174-2 may have the gate terminal (e.g., the second control terminal 122-2), the source terminal (e.g., the second bias input terminal 126-2), and the drain terminal (e.g., the second bias output terminal 124-2). It should be appreciated that the first amplifier stage 92-1 and the second amplifier stage 92-2 may use any viable switching circuitry in lieu of or in addition to the first P-channel device 174-1 and/or the second P-channel device 174-2, respectively.

The source terminal of the second P-channel device 174-2 may be coupled to the power source 29. As such, the source terminal of the second P-channel device 174-2 may receive the bias signal (e.g., VDD) for amplifying the modulated signal. Moreover, the drain terminal of the second P-channel device 174-2 may be coupled to the source terminal of the first P-channel device 174-1 via the second inductor 112-2. The second P-channel device 174-2 may output the bias signal by the respective drain terminal. As such, the source terminal of the first P-channel device 174-1 may receive the bias signal for amplifying the modulated signal. In some embodiments, the amplifier 89-2 may include a first bypass capacitor 134 coupling the first node 136 between the second inductor 112-2 and the first P-channel device 174-1 to the ground terminal. In some cases, the first bypass capacitor 134 may ground at least a portion of noises between the first amplifier stage 92-1 and the second amplifier stage 92-2.

The gate terminal of the first P-channel device 174-1 may be coupled to the amplifier input terminal 94 via a first coupling capacitor 130. The gate terminal of the first P-channel device 174-1 may receive the modulated signal (e.g., input signal, Vᵢₙ) for amplification. The first P-channel device 174-1 may amplify the input signal (e.g., Vᵢₙ) based on a gain when receiving the bias signal. The first amplifier stage 92-1 may output the modulated signal (e.g., the first output signal, Vₒᵤₜ₁), as amplified by the first P-channel device 174-1, by the drain terminal of the first P-channel device 174-1. The drain terminal of the first P-channel device 174-1 may be coupled to the ground terminal via the first inductor 112-1. Moreover, the drain terminal of the first P-channel device 174-1 may be coupled to the gate terminal of the second P-channel device 174-2 via a second coupling capacitor 132. As such, the gate terminal of the second P-channel device 174-2 may receive the modulated signal (e.g., the first output signal, Vₒᵤₜ₁), as amplified by the first P-channel device 174-1.

The second P-channel device 174-2 may amplify the input signal (e.g., Vᵢₙ) based on a gain when receiving the bias signal. It should be appreciated that the first P-channel device 174-1 and the second P-channel device 174-2 may provide equal, substantially or relatively equal, or different gain values. The second amplifier stage 92-2 may output the modulated signal (e.g., the second output signal, the amplified signal, Vₒᵤₜ₂), as amplified by the first P-channel device 174-1 and the second P-channel device 174-2, by the drain terminal of the second P-channel device 174-2. In the depicted embodiment, the drain terminal of the second P-channel device 174-2 may be coupled to the amplifier output terminal 96. As such, the amplifier 89-2 may output the second output signal (e.g., Vₒᵤₜ₂) as the amplified signal (e.g., Vₒᵤₜ) via the amplifier output terminal 96.

As discussed above, a frequency of the bias signal (e.g., VDD) may be zero (e.g., near zero, relatively zero) or below the frequency threshold. Moreover, the first amplifier stage 92-1 may receive the bias signal from the second amplifier stage 92-2 over the first node 136. As such, a frequency of the bias signal at the first node 136 between the first amplifier stage 92-1 and the second amplifier stage 92-2 may be zero (e.g., near zero, relatively zero) or below the frequency threshold. If not compensated for, in some cases, a non-linear gain expansion or compression of the first amplifier stage 92-1 and/or the second amplifier stage 92-2, among other things, may cause an undesired amplitude mis-match between the input signal (e.g., Vᵢₙ) and the amplified signal (e.g., Vₒᵤₜ) adversely affecting a signal quality of the amplified signal (e.g., Vₒᵤₜ) being generated and/or transmitted.

Similar to the example embodiments discussed above, the linearization circuitry 90 may reduce a voltage and/or current of the ripple signal and therefore improve the signal quality of the amplified signal carrying the outgoing data 60. The first OTA 116-1 may be coupled to the first node 136 between the first amplifier stage 92-1 and the second amplifier stage 92-2 to provide a low impedance ground path to signals having a frequency greater than or equal to the frequency threshold. As such, the first OTA 116-1 may reduce a voltage and/or current of the ripple signal by grounding at least a portion of the ripple signal (e.g., V_{OTA}). Moreover, the second P-channel gain correction circuit 119-2 may dampen, either compress or expand, an undesired gain expansion or compression of the first P-channel device 174-1 and/or the second P-channel device 174-2 to reduce a voltage and/or current of the undesired ripple signal (e.g., a remaining portion of the ripple signal). As discussed above, the second P-channel gain correction circuit 119-2 may include the second choke inductor 144-2, the first coupling capacitor 130, the first resistor 146 (e.g., the first resistor 146-1, 146-2, and/or 146-Y), the second resistor 148-2 (e.g., the second resistor 148-1, 148-2, and/or 148-Y), and the second current source 152-2.

In the depicted embodiment, the second choke inductor 144-2 may be coupled to the gate terminal of the second P-channel device 174-2 and the first coupling capacitor 130. The first resistor 146-2 may have a first terminal or port coupled to the second choke inductor 144-2, the second resistor 148-2, and the second current source 152-2, and a second terminal or port coupled to the first source terminal of second P-channel device 174-2. The second resistor 148-2 may have a second terminal or port coupled to the first resistor 146-2, the second current source 152-2, and the second choke inductor 144-2, and a first terminal or port coupled to the power source 29. The second current source 152-2 may be coupled to the first resistor 146-2, the second resistor 148-2, and the second choke inductor 144-2 to receive a supply voltage (e.g., the bias signal). For example, the second current source 152-2 may be coupled to power source 29 via the second resistor 148-2. Moreover, the second current source 152-2 may output electrical current to a ground terminal or port.

A resistance values of the first resistor 146-2 and the second resistor 148-2, an inductance value of the second choke inductor 144-2, and an output current value of the second current source 152-2 may be selected to reduce a voltage or current of the ripple signal. Referring now to FIG. 15, the graph 160 illustrates example gain value changes of the amplifiers 89 based on resistance values of the first resistor 146-1 and the second resistor 148-1. For example, a greater resistance value of the second resistor 148-2 (or the first resistor 146-2) compared to the first resistor 146-2 (or the second resistor 148-2) may boot-strap the second P-channel device 174-2 to reduce a voltage and/or current of the ripple signal by linearizing (e.g., compressing, reducing) an undesired gain expansion of the second P-channel device 174-2. Moreover, a greater resistance value of the first resistor 146-2 (or the second resistor 148-2) compared to the second resistor 148-2 (or the first resistor 146-2) may reduce the voltage and/or current of the ripple signal by linearizing (e.g., expanding, increasing) an undesired gain compression of the second P-channel device 174-2. Accordingly, the linearization circuitry 90 may reduce a non-linear gain expansion or compression of the amplifier 89-2.

Referring back to FIG. 13, the linearization circuitry 90 may include a first P-channel gain correction circuit 119-1 to reduce a non-linear gain expansion or compression of the amplifier 89-2. The first P-channel gain correction circuit 119-1 may be coupled to a first control terminal or port 122-1 and a first bias output terminal or port 124-1 of the first P-channel device 110-1. The first P-channel gain correction circuit 119-1 may include a first choke inductor 144-1, the first coupling capacitor 130, a first resistor 146-1, a first resistor 148-1, and a first current source 152-1.

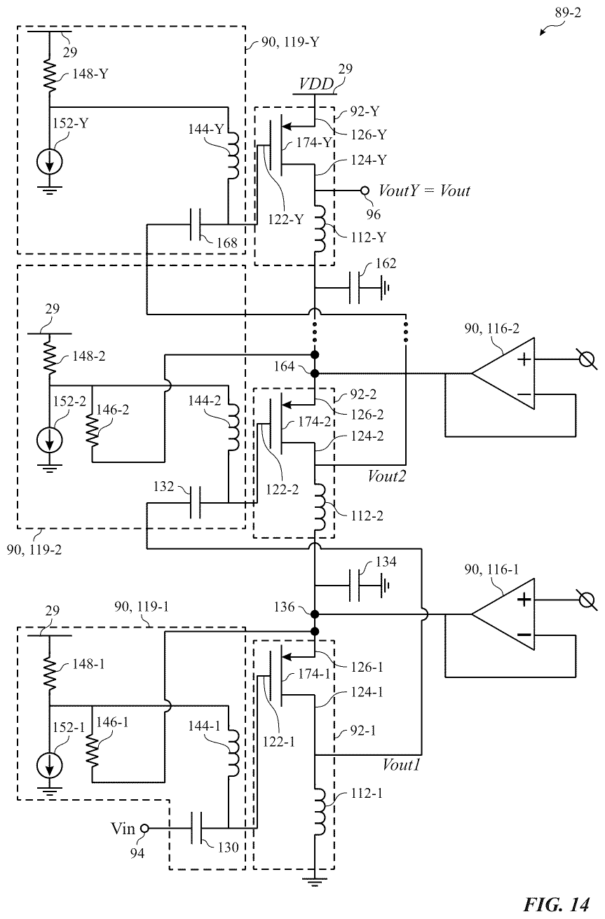

FIG. 14 is a schematic diagram of the amplifier 89-2 including the linearization circuitry 90 and the first amplifier stage 92-1 having the first P-channel device 174-1 reverse-stacked with the second amplifier stage 92-2 having the second P-channel device 174-2 and at least the Yth amplifier stage 92-Y having a Yth P-channel device 174-Y, according to embodiments of the present disclosure. Each amplifier stage 92 may include a respective P-channel device and a respective inductor. For example, in the depicted embodiment, the first amplifier stage 92-1 may include the first inductor 112-1 and the first P-channel device 174-1, the second amplifier stage 92-2 may include a second inductor 112-2 and the second P-channel device 174-2, and the Yth amplifier stage 92-Y may include the Yth inductor 112-Y and a Yth P-channel device 174-Y (e.g., the Yth switching device).

It should be appreciated that the amplifier 89-2 may include any viable number of amplifier stages 92 (e.g., 2, 3, 4, 5, and so on, N). Each P-channel device may include any viable P-channel transistor such as a MOSFET, among other possibilities. Moreover, the first amplifier stage 92-1 and/or the second amplifier stage 92-2 may include additional or alternative circuit components. For example, each amplifier stage 92 may include one or more N-channel devices 110 in lieu or in addition to the respective P-channel device and/or a transformer in lieu of or in addition to the respective inductor.

The first P-channel device 174-1 may have the gate terminal (e.g., the first control terminal 122-1), the drain terminal (e.g., the first bias input terminal 126-1), and the source terminal (e.g., the first bias output terminal 124-1). The second P-channel device 174-2 may have the gate terminal (e.g., the second control terminal 122-2), a drain terminal (e.g., the second bias input terminal 126-2), and the source terminal (e.g., the second bias output terminal 124-2). Similarly, the Yth P-channel device 174-Y may have a gate terminal (e.g., a Yth control terminal 122-Y), a drain terminal (e.g., a Yth bias input terminal 126-Y), and a source terminal (e.g., a Yth bias output terminal 124-Y). It should be appreciated that each amplifier stage 92 may use any viable switching circuitry in lieu of or in addition to the respective P-channel devices 174.

In the depicted embodiment, the Yth bias input terminal 126-Y of the Yth P-channel device 174-Y may be coupled to the power source 29. Moreover, the Yth bias output terminal 124-Y of the Yth P-channel device 174-Y may be coupled to a bias input terminal of a previous P-channel device via the first inductor 112-1. In the depicted embodiment, the Yth bias output terminal 124-Y of the Yth P-channel device 174-Y may be coupled to the second bias input terminal 126-2 of the second P-channel device 174-2 via the first inductor 112-1. As such, the Yth P-channel device 174-Y may receive the bias signal (e.g., VDD) from the power source 29 and output (e.g., share) the bias signal to the second P-channel device 174-2.

The second bias output terminal 124-2 may be coupled to the first bias input terminal 126-1 of the first P-channel device 174-1 via the second inductor 112-2. As such, the first bias input terminal 126-1 of the first P-channel device 174-1 may receive the bias signal. That is, the P-channel device of each amplifier stage 92 may share the bias signal with a previous amplifier stage. As mentioned above, the amplifier 89-2 may include any viable number of amplifier stages 92. Accordingly, the Yth bias output terminal 124-Y may be coupled to any number of additional P-channel devices not shown before the bias signal is shared with the second P-channel device 174-2.

The amplifier stages 92 are cascaded such that each amplifier stage 92 may output a respective output signal to a subsequent amplifier stage. The first control terminal 122-1 of the first P-channel device 174-1 may be coupled to the amplifier input terminal 94 via the first coupling capacitor 130 to receive the input signal (e.g., Vᵢₙ). The first P-channel device 174-1 may amplify the input signal (e.g., Vᵢₙ) based on a gain. The first amplifier stage 92-1 may output the modulated signal (e.g., the first output signal, Vₒᵤₜ₁), as amplified by the first P-channel device 174-1, by the first bias output terminal 124-1 of the first P-channel device 174-1.

The first bias output terminal 124-1 of the first P-channel device 174-1 may be coupled to the second control terminal 122-2 of the second P-channel device 174-2 via the second coupling capacitor 132. As such, the second P-channel device 174-2 may receive the modulated signal (e.g., the first output signal, Vₒᵤₜ₁), as amplified by the first P-channel device 174-1. Similarly, the second amplifier stage 92-2 may output the modulated signal (e.g., the second output signal, Vₒᵤₜ₂), as amplified by the first P-channel device 174-1 and the second P-channel device 174-2, by the second bias output terminal 124-2 of the second P-channel device 174-2.

The second bias output terminal 124-2 of the second P-channel device 174-2 may be coupled to a control terminal of a subsequent P-channel device. In the depicted embodiment, the second bias output terminal 124-2 of the second P-channel device 174-2 may be coupled to the Yth control terminal 122-Y of the Yth P-channel device 174-Y via a Yth coupling capacitor 168. As such, the Yth P-channel device 174-Y may receive the modulated signal (e.g., the second output signal, Vₒᵤₜ₂), as amplified by the first P-channel device 174-1 and the second P-channel device 174-2. The Yth bias output terminal 124-Y of the Yth P-channel device 174-Y may be coupled to the amplifier output terminal 96. Accordingly, the amplifier 89-2 may output the Yth output signal (e.g., V_{outY}) as the amplified signal (e.g., Vₒᵤₜ) via the amplifier output terminal 96. As mentioned above, the amplifier 89-2 may include any viable number of amplifier stages 92 (e.g., 2, 3, 4, 5, and so on, Y).

It should be appreciated that each P-channel device may amplify the input signal based on equal, substantially or relatively equal, or different gain values. In some embodiments, the amplifier 89-2 may include the first bypass capacitor 134 and the second bypass capacitor 162 coupling the second node 164 between the second P-channel device 174-2 and the Yth inductor 112-Y to the ground terminal. In some cases, the second bypass capacitor 162 may ground at least a portion of noises between the second P-channel device 174-2 and the Yth inductor 112-Y.

In the depicted embodiment, the linearization circuitry 90 may include the first OTA 116-1, the second OTA 116-2, the Yth OTA 116-Y, the first P-channel gain correction circuit 119-1, the second P-channel gain correction circuit 119-2, and the Yth P-channel gain correction circuit 119-Y. In some cases, the linearization circuitry 90 may reduce a voltage and/or current of one or more undesired ripple signals, for example, on the first node 136 and/or the second node 164. As such, the linearization circuitry 90 may improve the signal quality of the amplified signal carrying the outgoing data 60.

The first OTA 116-1 may be coupled to the first bias output terminal 124-1 of the first amplifier stage 92-1 and the second bias output terminal 124-2 of the second amplifier stage 92-2. The second OTA 116-2 may be coupled to the second bias output terminal 124-2 of the second amplifier stage 92-2 and the Yth bias output terminal 124-Y of the Yth amplifier stage 92-Y. It should be appreciated that the linearization circuitry 90 may include one or more additional OTAs, for example, coupled to a bias input terminal and/or a bias output terminal of one or more additional amplifier stages 92 not shown for simplicity.

Each OTA 116 may provide a low impedance ground path to signals having a frequency greater than or equal to the frequency threshold to reduce a voltage and/or current of an undesired ripple signal. As discussed above, the OTAs 116 may draw at least a portion of electrical currents of an undesired ripple signal to reduce a voltage and/or power of the undesired ripple signal. Accordingly, the OTAs 116 may reduce undesired (e.g., non-linear) behavior of amplifier 89-2 and/or improve the signal quality of the amplified signal carrying the outgoing data 60.

The gain correction circuits 118 may be coupled to a control terminal and/or a bias output terminal of a respective amplifier stage. In some embodiments, each P-channel gain correction circuit 119 may include a choke inductor 144, a coupling capacitor (e.g., the first coupling capacitor 130, the second coupling capacitor 132, the Yth coupling capacitor 168), a first resistor 146 (e.g., the first resistor 146-1, 146-2, and/or 146-Y), a second resistor 148 (e.g., the second resistor 148-1, 148-2, and/or 148-Y), and a current source 152 (e.g., the current sources 152-1, 152-2, and 152-Y). In the depicted embodiment, the first P-channel gain correction circuit 119-1 may not include a respective first resistor 146. Alternatively or additionally, the first P-channel gain correction circuit 119-1 may include a respective first resistor 146 coupled to the first bias output terminal 124-1 of the first P-channel device 174-1.

It should be appreciated that the linearization circuitry 90 may include one or more additional gain correction circuits, for example, coupled to a control terminal and a bias output terminal of one or more additional P-channel device (not shown). Each P-channel gain correction circuit 119 may reduce a voltage or current of an undesired ripple signal. Accordingly, the linearization circuitry 90, including the OTAs 116 and the gain correction circuits 118, may reduce a non-linear gain expansion or compression of the amplifier 89-2.

FIG. 15 is the graph 160 illustrating gain value changes (in decibels (dB)) across input power (Pin) of the amplifiers 89 based on resistance values of the resistors 146 and the second resistors 148, in accordance with embodiments of the present disclosure. It should be appreciated that the graph 160 is provided by way of example. Moreover, the gain value of the amplifiers 89 discussed above, resistance values of the first resistors 146 and second resistors 148, and the input power of the input signal may be selected differently in different embodiments.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. An electronic device comprising:
an antenna; and
an amplifier comprising:
a first switching device coupled to an amplifier input terminal of the amplifier;
a second switching device coupled to the first switching device and the antenna; and
a transconductance amplifier having a first input terminal, a second input terminal, and an output terminal,
the first input terminal coupled to a controlled voltage source, and
the output terminal coupled to the first switching device, the second switching device, and the second input terminal.

2. The electronic device of claim 1, wherein the transconductance amplifier is configured to
provide an impedance less than an impedance threshold based on receiving signals having a frequency greater than a frequency threshold via the output terminal, and
provide an impedance greater than or equal to the impedance threshold based on receiving signals having a frequency equal to or less than the frequency threshold via the output terminal.

3. The electronic device of claim 1, comprising a power source configured to output a bias signal to the amplifier.

4. The electronic device of claim 3, wherein only one of the first switching device and the second switching device is coupled to the power source.

5. The electronic device of claim 1, comprising a gain correction circuit coupled to a control terminal of the first switching device or the second switching device.

6. The electronic device of claim 5, wherein the gain correction circuit comprises a choke inductor coupled to the control terminal, a current source circuit coupled to the choke inductor, and a first resistor coupled to the choke inductor and the current source circuit.

7. The electronic device of claim 6, wherein the gain correction circuit comprises a second resistor having a first terminal coupled to the choke inductor, the current source circuit, and the first terminal of the first resistor, and having a second terminal coupled to a bias output terminal of the first switching device or the second switching device.

8. The electronic device of claim 1, comprising a modulator coupled to the amplifier.

9. The electronic device of claim 8, wherein the modulator is configured to generate a modulated signal based on transmission data and a carrier signal, the amplifier being configured to amplify the modulated signal, and the antenna being configured to transmit wireless signals based on the modulated signal as amplified by the amplifier.

10. Wireless transmission circuitry comprising:
a first amplifier stage configured to receive a bias signal and an input signal, the first amplifier stage configured to generate an output signal based on the bias signal and the input signal;
a second amplifier stage coupled to the first amplifier stage, the second amplifier stage configured to receive the bias signal and the output signal, and generate an amplified signal based on the bias signal and the output signal; and
a transconductance amplifier coupled to the first amplifier stage and the second amplifier stage, the transconductance amplifier having
a first input terminal coupled to a controlled voltage source,
a second input terminal, and
an output terminal coupled to the first switching device, the second switching device, and the second input terminal, the transconductance amplifier configured to provide an impedance based on a frequency of a signal received at the second input terminal.

11. The wireless transmission circuitry of claim 10, wherein the first amplifier stage comprises a first switching device and the second amplifier stage comprises a second switching device.

12. The wireless transmission circuitry of claim 10, wherein the first amplifier stage is configured to generate the output signal by amplifying the input signal based on a first gain, and the second amplifier stage is configured to generate the amplified signal by amplifying the output signal based on a second gain.

13. The wireless transmission circuitry of claim 10, wherein one of the first amplifier stage and the second amplifier stage is configured to receive the bias signal directly from a power source and provide the received bias signal with another one of the first amplifier stage and the second amplifier stage.

14. The wireless transmission circuitry of claim 10, comprising a gain correction circuit coupled to one of the first amplifier stage and the second amplifier stage, wherein the gain correction circuit is configured to decrease or increase a gain of the first amplifier stage or the second amplifier stage.

15. The wireless transmission circuitry of claim 14, wherein the gain correction circuit comprises a choke inductor coupled to the first amplifier stage or the second amplifier stage, a current source circuit coupled to the choke inductor, and a first resistor coupled to the choke inductor and the current source circuit.

16. An amplifier comprising:
a first switching device coupled to an amplifier input terminal of the amplifier;
a second switching device coupled to the first switching device and an amplifier output terminal of the amplifier; and
a transconductance amplifier coupled to the first switching device and the second switching device, the transconductance amplifier configured to
provide an impedance less than an impedance threshold based on signals with a frequency greater than a frequency threshold, and
provide an impedance greater than or equal to the impedance threshold based on signals with a frequency equal to or less than the frequency threshold.

17. The amplifier of claim 16, wherein the first switching device and the second switching device are configured to receive a single bias signal of a power source.

18. The amplifier of claim 17, wherein the first switching device is configured to generate an output signal based on the single bias signal and an input signal, and the second switching device is configured to generate an amplified signal based on the bias signal and the output signal.

19. The amplifier of claim 16, comprising a gain correction circuit coupled to a control terminal of the first switching device or the second switching device, wherein the gain correction circuit comprises a choke inductor coupled to the control terminal, a current source circuit coupled to the choke inductor, and a first resistor coupled to the choke inductor and the current source circuit.

20. The amplifier of claim 19, wherein the gain correction circuit is configured to decrease or increase a gain of the first switching device or the second switching device.
